(19) United States
(12) Patent Application Publication
(10) Pub. No.: US 2005/0117038 A1
(43) Pub. Date: Jun. 2, 2005

(54) Smear evaluation circuit, image pickup apparatus and method of driving solid-state image sensor

(75) Inventor: Hisashi Matsuyama, Ryoke-cho (JP)

Correspondence Address: OLIFF & BERRIDGE, PLC, P.O. BOX 19928, ALEXANDRIA, VA, 22320, US

(73) Assignee: SANYO ELECTRIC CO., LTD., Moriguchi-shi (JP)

(21) Appl. No.: 10/992,832

(22) Filed: Nov. 22, 2004

(30) Foreign Application Priority Data
Nov. 28, 2003 (JP) 2003-398658
Sep. 17, 2004 (JP) 2004-271947

(51) Int. Cl. H01L 27/148; H01L 29/74; H01L 29/768; H04N 9/64; H04N 1/38; H01L 27/00

(52) U.S. Cl. 348/249; 358/463; 250/208.1

(57) ABSTRACT

In a frame transfer CCD image sensor, the frame rate is improved while suppressing a smear component in the case that the image from a part of the imaging portion is used. A smear evaluation circuit obtains the smear component of each line of image signal V(j) of a center area which is an image extraction target from an accumulated value of preceding lines of image signal. Here, contribution of the smear component from the preceding read area of the center area is estimated based on the image signal of the first line of the center area, without using the accumulation of the image signals of the preceding read area. This estimate value is set in a line memory as a smear component initial value and an accumulating process for each line of the center area begins. Thereby, the read of the image signal of the preceding read area is omitted and thus the frame rate is improved.

### BACKGROUND OF THE INVENTION

The present invention relates to a smear evaluation circuit, an image pickup apparatus and a method of driving a solid-state image sensor which obtain a smear component which can be included in an image signal of a frame transfer CCD image sensor.

In an image pickup apparatus of generating the image signal by using a solid-state image sensor or the like, the magnification of the image can be performed by an optical zoom using a lens as well as a zoom according to a signal process (digital zoom) Particularly, in the image pickup apparatus using the solid-state image sensor, sufficient resolution can be obtained in accompanying with an increase of the number of the pixel of the solid-state image sensor although the digital zoom is performed.

Conventionally, the digital zoom is realized by reading the signal charges of the overall pixels of the imaging portion of the solid-state image sensor as the image signals and signal-processing the part corresponding to the magnification target area of the image signals.

In the frame transfer CCD (charge coupled device) image sensor, there is a problem in that a smear component is mixed to the image signal read from the image sensor because of the structure thereof. This is because, in the frame transfer CCD image sensor, the imaging portion itself is composed of a number of vertical CCD shift registers so that the signal charge is transferred to the column direction (a vertical direction on the image) of the unshielded imaging portion when moving the signal charge accumulated in each cell (pixel) of the imaging portion to the shielded storage portion in the frame transfer operation. That is, the signal charge is located in each cell to the storage portion for a clock cycle of the frame transfer. The signal charges due to the light reception at the locations passing through during the frame transfer add to the original signal charge, and these additional charges make the smear component. More specifically, if there is the cell which receives strong light and generates more smear components, a linear noise having high luminescence downwardly extending from the corresponding cell appears in the output image, thereby remarkably deteriorating the image quality. Hereinafter, the mechanism of the vertical transfer in the imaging portion and the storage portion and the above-mentioned smear generation according to the frame transfer will be described with reference to drawings.

FIG. 1 is a schematic plan view of a frame transfer CCD image sensor. An image sensor 2 comprises an imaging portion 2i, a storage portion 2s, a horizontal transfer portion 2h and an output portion 2d. The imaging portion 2i and the storage portion 2s are composed of vertical CCD shift registers whose channels are continuous with each other in a column direction, and a plurality of the vertical CCD shift registers are arranged in the line direction (the horizontal direction on the image) in the imaging portion 2i and the storage portion 2s. The cell composing each bit of the vertical CCD shift register of the imaging portion 2i generates and accumulates the signal charge according to incident light. If the set exposure time elapses, the signal charges in the imaging portion 2i are frame-transferred to the storage portion 2s. Since the storage portion 2s is covered with a light shielding layer and thus the charge is prevented from generating due to the incident light, the signal charge frame-transferred from the imaging portion 2i can be maintained as it is. The horizontal transfer portion 2h is composed of the CCD shift register, and each bit is connected to each output of a plurality of vertical CCD shift registers of the storage portion 2s. The signal charges for one screen which are maintained in the storage portion 2s are transferred to the horizontal transfer portion 2h as the unit of one line. The horizontal transfer portion 2h sequentially transfers the signal charges for one line to the output portion 2d. The output portion 2d is composed of an electrically isolating capacity and an amplifier for obtaining the potential variation of the capacity, and receives the signal charges output from the horizontal transfer portion 2h in the capacity as the unit of one bit, converts it into a voltage value, and outputs it as a sequential image signal.

FIG. 2 is a schematic partial cross sectional view showing a structure of the vertical CCD shift register constituting the imaging portion 2i and a storage portion 2s of the frame transfer CCD image sensor. A substrate has an npn-type structure in the depth direction thereof, which is composed of an n-type semiconductor substrate 4, a p-well 6 formed by diffusing p-type impurities thereon, and an n-type area 8 formed by diffusing n-type impurities such that the depth from the surface of the substrate is shallower than that of the p-well 6. On the surface of the substrate, a plurality f gate electrodes 10 is arranged in the column direction through silicon oxide layer (not shown). Three-phase clock are applied to the gate electrodes 10, and the channel potential in the semiconductor substrate under the silicon oxide film is controlled according to the clock voltage. In the imaging portion, three-phase clocks φi1 to φi3 are respectively applied to the gate electrodes 10-1 to 10-3, and, in the storage portion, three-phase clocks φs 1 to φs3 are applied to the gate electrodes. In the storage portion, a light shielding layer (not shown) is provided on the gate electrodes 10.

FIG. 3 is a schematic diagram showing a potential profile in a substrate direction of the npn-type CCD shift register. In FIG. 3, a horizontal axis shows a depth from the surface of the substrate. In addition, a vertical axis shows the potential, wherein a lower side thereof is a positive potential side and an upper side thereof is a negative potential side. A curve 12 (ABC) shows a potential profile when applying an ON voltage of a transfer clock (a predetermined positive voltage) to the gate electrode 10, and a curve 14 (A′BC) shows a potential profile when applying an OFF voltage of the transfer clock (a predetermined voltage lower than the ON voltage) to the gate electrode 10. When applying the ON voltage to the gate electrode, a potential well is formed in an area 16 close to the surface of the substrate and thus electrons can be stored in the potential well. On the other hand, when applying the OFF voltage to the gate electrode, the potential well disappears. For example, upon the exposure, if the transfer clock φi2 applied to the gate electrode 10-2 of the imaging portion is the ON voltage and the transfer clocks φi1 and φi3 applied to each of the gate electrodes 10-1 and 10-3 adjacent to the gate electrode 10-2 are the OFF voltage, the potential well is formed under the gate electrode 10-2 and thus the signal charge generated according to the incident light is accumulated in the potential well. Next, when transferring the signal charge toward the storage portion, the signal charge is moved from under the gate electrode 10-2 to under the gate electrode 10-3 by turning on the clock φi3 and then turning off the clock φi2. Similarly, the movement of the signal charge from under the gate electrode 10-3 to under the gate electrode 10-1 and the movement of the signal charge from under the gate electrode 10-1 to under the gate electrode 10-2 are performed. In the frame transfer, the movements of the signal charge between the electrodes are repeated at a high speed and thus the signal charge is moved from the imaging portion to the storage portion.

FIG. 4 is a schematic diagram illustrating the generation of the smear. Here, the case in which the imaging portion 2i and the storage portion 2s have only 4 cells with respect to the column direction, respectively, is shown. In FIG. 4, at each of times t1 to t4 for each transfer clock period T after t0 and t0 which an exposure period E is completed, four cells I(1) to I(4) of the imaging portion 2i and four cells S(1) to S(4) of the storage portion 2s are arranged in the horizontal direction along to the arrangement order in the column. Here, each box shape corresponds to each cell, a net line shown in the box shape shows a signal charge Q_{image} generated at the exposure period E and an oblique line shows a smear component Qₛₘₑₐᵣ. When the exposure is completed, the frame transfer according to the transfer clock of the period T begins and the signal charges accumulated in each cell of the imaging portion 2i are moved toward the storage portion 2s for each period T one cell by one cell in the column direction. Also, each cell is allocated with one set of gate electrodes 10-1 to 10-3 and the signal charges are sequentially transferred under three gate electrode during the period T.

In FIG. 4, the time t0 is the timing that the exposure of each cell is completed. In addition, the state corresponding to the time ti (i=1 to 4) shows the signal charge moved by i cell in the column direction. In the time t1 (=t0+T), the signal charge Q_{image}(1) generated at the cell I(1) adjacent to the storage portion is transferred to the cell S(4) of the storage portion without adding the smear component, while the signal charges Q_{image}(2) to Q_{image}(4) generated at the remaining cells I(2) to I(4) are transferred to the cells I(1) to I(3), respectively, and the charges of the smear component Qₛₘₑₐᵣ(1) to Qₛₘₑₐᵣ(3) are added to the transferred cells, respectively. At the times (t2 to t4), similarly, the signal charges which are stored in the imaging portion other than the signal charge which is moved to the cell I(1) adjacent to the storage portion have an accumulating smear component in the transferred cell, respectively. The time t4 shows a state that the frame transfer is completed, and the smear component is accumulated in the signal charge Q_{image} (j) generated at the cell I(j) for each cell of the passing imaging portion in the frame transfer. The signal charge amount corresponding to the cell I(j) including the smear component is hereinafter represented by Q(j). The signal charges frame-transferred to the storage portion are sequentially transferred to the output portion by the horizontal transfer portion and the output portion generates and outputs the image signal V(j) according to the signal charge Q(j) with respect to each cell of the imaging portion.

There is a method for evaluating and removing the smear component by the signal process for the image signal output from the solid-state image sensor. As can be seen from the explanation of the example shown in FIG. 4, after the exposure period E is completed, the image signal V(j) corresponding to the signal charge amount Q(j) of the cell I(j) moved from the imaging portion to the storage portion at the n-th period of the frame transfer clock is expressed as follows. Here, V_{image}(j) and Vₛₘₑₐᵣ(n) express the voltage values obtained from the out portion in correspondence with the signal charge Q_{image} (j) and the charge of the smear component Qₛₘₑₐᵣ(n), respectively.

$${V}_{( j )} = {V}_{image ( j )} + {\sum }_{n = 1}^{j - 1} {V}_{smear ( n )} \qquad ( 1 )$$

Here, in the case in which the incident light strength for each cell of the imaging portion at the exposure period E and the frame transfer period (transfer clock period T) is considered to be time-constant, Vₛₘₑₐᵣ(n) is proportional to V_{image}(n) and can be obtained by a next equation.
Vₛₘₑₐᵣ(n)=V_{image}(n)·T/E (2)

Based on the equations (1) and (2), the image signal V_{image}(j) which does not include the smear component can be obtained from image signals V(n) (n=1 to j−1) which are previously output. In detail, for example, from V(1)=V_{image}(1), V_{image}(2) is obtained by a next equation.
V_{image}(2)=V(2)−V_{image}(1)·T/E (3)

As such, from the V_{image}(n) (n=1 to j−1) obtained based on the image signal V(n) output from the output portion and the image signal V(j) newly output from the output portion, the image signal V_{image}(j) which does not include the smear component can be obtained by the next equation.

$${V}_{image ( j )} = {V}_{( j )} - \frac{T}{E} \cdot {\sum }_{n = 1}^{j - 1} {V}_{image ( n )} \qquad ( 4 )$$

FIG. 5 is a block diagram of a smear removing circuit for removing the smear component by performing the above-mentioned signal process. This circuit receives the image signal V(j) output from the output portion and removes the smear component Vₛₘₑₐᵣ(j) from that to output V_{image}(j). The smear removing circuit comprises a smear evaluation circuit 20 for obtaining the smear component included in V(j) and a subtracting circuit 22 for removing the smear component from V(j) to obtain V_{image}(j). The smear evaluation circuit 20 is a circuit for operating the second term of the right side in the equation (4) and the subtracting circuit 22 is a circuit for subtracting the second term from the first term in the equation (4).

The smear evaluation circuit 20 includes an adding circuit 24, a line memory 26 and a multiplying circuit 28. The line memory 26 can store the signal for one line of the solid-state image sensor, and, at the timing that the j-th image signal V(j) is output from the solid-state image sensor, the value obtained by accumulating V_{image} from the first line to the (j−1)-th line for each column is stored. The content stored in the line memory 26 is read from the line head in sequence. The multiplying circuit 28 multiplies the value read from the line memory 26 by the coefficient (T/E) and obtains the smear component value included in the image signal V(j) of the j-th line to output it to the subtracting circuit 22. In the subtracting circuit 22, the timing that the smear component value obtained by the multiplying circuit 28 is input to the subtracting circuit 22 is adjusted such that the smear component value corresponding to the k-th column is subtracted from the image signal value corresponding to the k-th column of the solid-state image sensor (k is any column number). The subtracting circuit 22 outputs the j-th line of the image signal V_{image}(j) in which the smear component is removed and the output signal is supplied to the image process of the back-end (not shown). On the other hand, V_{image}(j) is also input to the adding circuit 24 of the smear evaluation circuit 20. The adding circuit 24 reads the adding value of the V_{image} from the first line to the (j−1)-th line from the line memory 26 and adds this value to V_{image}(j) output from the subtracting circuit 22, and the added value is stored in the line memory 26. Thereby, the accumulated value of the V_{image} stored in the line memory 26 is updated to the sum from the first line to the j-th line.

In addition, the conventional smear removing circuit shown in FIG. 5 is shown in JP 3157455B2 (JP 9270957).

The process of extracting the image of a part of the imaging portion of the solid-state image sensor can be used in the digital zoom as mentioned above.

Here, in a digital camera and other equipment like a portable terminal having the camera function, the pixel number of the solid-state image sensor is remarkably improved, compared to that of the pixel number of a monitor for preview. For this reason, an image having a high resolution according to the pixel number of the solid-state image sensor is photographed when recording the image in a recording medium such as a memory, but the photographing may be performed with the small number of pixel according to the pixel number of the preview monitor upon the preview. Also, in the visual characteristics of a person, a dynamic image does not need the high resolution as a still image and there is a case that the photographing with the pixel number less than that of the still image is selected in order to suppress the recording data amount. In this case, the process of obtaining and using the image of a part of the imaging portion of the solid-state image sensor may be performed.

However, in the conventional art for evaluating the smear component through the image signal process, the previously read V_{image} of each line is required in order to evaluate the smear component included in the j-th line of image signal V(j) output from the solid-state image sensor. In other words, in the conventional art, even when a partial area of the imaging portion 2i of the solid-state image sensor is an extraction target of the image signal, the image signal of the area located between the storage portion 2s and the extraction target area, hereinafter called offset area, should be read in order to evaluate the smear component included therein.

As such, in driving the solid-state image sensor, the number of the horizontally transferred lines becomes larger than that of the lines constituting the extraction target area, in order to read the area other than the extraction target. At the result, the frame rate of the preview or the dynamic image photograph can not increase and thus the smooth movement of the image can not be expressed or a power required for the driving of the horizontal transfer portion increases.

Also, in the conventional art, the circuit shown in FIG. 5 is also operated with respect to the image signal other than the extraction target area and thus the accumulating operation expressed by the equation (4) should be performed. In order to reduce the power consumption in the recent image pickup apparatus, the effort for stopping the driving of each block constituting the image signal process circuit in the period which does not need the process is made. In this view, the conventional art that the circuit of FIG. 5 should be operated in the area other than the extraction target area has room for reducing the power consumption.

### SUMMARY OF THE INVENTION

The present invention is to solve the above-mentioned problems and it is an object of the present invention to provide a smear evaluation circuit, an image pickup apparatus and a method of driving a solid-state image sensor that a smear can be easily obtained and removed by a signal process while ensuring a high frame rate or a low power consumption when only an image of an image extraction target area set in a part of an imaging portion of a solid-state image sensor is used.

According to the present invention, a smear evaluation circuit for obtaining a smear amount mixed into a signal charge by the frame transfer from an imaging portion to a storage portion, based on image signals obtained by a solid-state image sensor including the imaging portion in which plurality of pixels capable of accumulating signal charges and transferring them in a column direction are arranged in a matrix and the storage portion for receiving the signal charges stored in the plurality of the pixels from the imaging portion in the column direction and temporally storing them therein, comprises, based on image data corresponding to each of the pixels of a predetermined image extraction target area set in the imaging portion and a ratio between an exposure period and a transfer period per one line of the frame transfer, an accumulating unit for estimating a smear component generated at the corresponding pixel, sequentially accumulating the smear component obtained for each of the pixels arranged in the image extraction target area in the column direction in accordance with the output sequence of the image signals, and outputting present accumulated data obtained for each column as a smear amount included in the image data corresponding the following pixel in the corresponding column; and, for each column, an initial value setting unit for setting a smear component initial value according to a smear amount generated at an offset area located between the storage portion and the image extraction target area of the imaging portion in the accumulating unit, as an initial of the accumulated data.

The smear amount mixed into the signal charge of any pixel (object pixel) of the imaging portion is originally the accumulated value of the smear components generated at each pixel passing while the signal charge of the corresponding object pixel is frame-transferred to the storage portion. That is, when obtaining the smear amount, in the pixel column to which the object pixel belongs, the smear amount generated at each pixel from the pixel adjacent to the storage portion to the pixel immediately previous to the corresponding object pixel should be accumulated. In this regard, the accumulating unit accumulates the smear components generated at the pixels from the top pixel (the pixel adjacent to the offset area) of the image extraction target area to the pixel immediately previous to the corresponding object pixel in the pixel column to which the object pixel belongs, without accumulating the smear components in the pixel located in the offset area. Here, the initial value setting unit sets the smear component initial value according to the smear amount generated at the offset area to the accumulating unit and the accumulating unit performs the accumulating operation by using the smear component initial value as the initial value, so that the accumulated result in the corresponding accumulating unit applies the estimate value of the smear amount for the signal charge of the object pixel. According to this structure, the signal charges of the lines corresponding to the offset area do not need to be read from the solid-state image sensor in order to obtain the smear component, and the horizontal transfer operation is omitted and thus the frame rate can be increased. Also, the operation of the accumulating unit in the offset area can be stopped, thereby reducing the power consumption.

The smear evaluation circuit according to the present invention further comprises an initial value estimating unit for estimating the image data at the offset area based on the image data of the line adjacent to the offset area of the image extraction target area and determining the smear component initial value based on the estimated image data.

The top line of the image extraction target area is adjacent to the offset area, and thus the correlation between the image data of the corresponding top line and the image data of the offset area can be expected. Accordingly, in the present invention, the image data of the offset area is estimated based on the image data of the corresponding top line. In a simple example, the image data of each column of the offset area is equal to the image data of the pixel belong to the same column of the top line. The smear component generated at each pixel of the offset area can be estimated by using the estimate value of the image data in the corresponding pixel. For example, the estimate can be performed based on the estimate value of the image data and the ratio of the exposure period and the transfer period per one line of the frame transfer, similarly to the accumulating unit. For example, in the case that the image which is viewed in the top line of the offset area and the image extraction target area has high equality, that is, in the case of the image having low spatial variation, the smear component initial value can be adequately estimated based on the top line of the image extraction target area. The image having high equality is, for example, sky, sea, or wall.

An image device according to the present invention comprises a solid-state image sensor having an imaging portion in which plurality of pixels capable of accumulating signal charges and transferring them in a column direction are arranged in a matrix, a storage portion for receiving the signal charges stored in the plurality of the pixels from the imaging portion in the column direction and temporally storing them therein, and a charge removing means which can remove the signal charge generated in an offset area inserted into the storage portion and a predetermined image extraction target area set in the imaging portion; a driving circuit which can perform an image extracting operation for removing the signal charge in the offset area from the solid-state image sensor by the charge removing means and selectively reading an image signal in the image extraction target area from the solid-state image sensor and an offset area read operation for reading an image signal of the offset area from the solid-state image sensor; based on the image data corresponding to each pixel of the imaging portion and a ratio between an exposure period and a transfer period per one line of the frame transfer, an accumulating unit for estimating a smear component generated in the corresponding pixel, sequentially accumulating the smear component obtained for each of the pixels arranged in the imaging portion in the column direction in accordance with the output sequence of the image signals from the solid-state image sensor, and outputting present accumulated data obtained for each column as a smear amount included in the image data corresponding the following pixel in the corresponding column; and, for each column, an initial value setting unit for setting a smear component initial value according to a smear amount generated at the offset area in the accumulating unit, as an initial value of the accumulated data, in the image extracting operation, wherein the driving circuit repeatedly performs the image extracting operation and performs the offset area read operation in a predetermined period, and the initial value setting unit sets the accumulated result of the accumulating unit in the offset area read operation as the smear component initial value used in the subsequent image extracting operation.

According to the present invention, the solid-state image sensor can remove the signal charges generated at the offset area from the solid-state image sensor. For example, the solid-state image sensor allows the vertical transfer electrodes corresponding to the offset area and the remaining vertical transfer electrodes at the imaging portion or the storage portion to be separately driven, and allows the signal charges stored in the portion corresponding to the offset area to be exhausted to the rear surface of the substrate, similarly to the electronic shutter. In the case of removing the signal charges of the offset area, the horizontal transfer can be omitted with respect to the line corresponding to the offset area and the horizontal transfer begins at the line corresponding to the image extraction target area. In this case, the read of the offset area is omitted and the image signals corresponding to the image extraction target area are selectively output from the solid-state image sensor (image extracting operation). On the other hand, the solid-state image sensor can read the image signals, without removing the signal charge of the offset area (offset area read operation). The accumulating unit performs the accumulating operation of the smear components from the top to the bottom of each pixel column of the offset area, in the offset area read operation. The initial value setting unit sets the accumulating result of the offset area read operation in the accumulating unit as the smear component initial value. In the image extraction operation, accumulating unit performs the accumulating operation of the smear components from the pixel of the top line to the pixel immediately previous to the object pixel in the image extraction target area with the use of the smear component initial value set in the offset area read operation as the initial value of the accumulating operation. For example, the offset area read operation and the image extracting operation can be alternately performed and one offset area read operation can be performed in plurality of the image extracting operations. The frequency of the offset area read operation can be determined in accordance with a desired frame rate (the frequency of the image extracting operation).

An image: device according to the present invention comprises a solid-state image sensor having an imaging portion in which a plurality of pixels capable of accumulating a signal charge and transferring it in a column direction is arranged in a matrix, a storage portion for receiving the signal charges stored in the plurality of the pixels from the imaging portion in the column direction and temporally storing them therein and an imaging portion charge removing means which can remove the signal charges from an area including at least a predetermined offset area adjacent to the storage portion in the imaging portion; a driving circuit which can perform an image extracting operation for selectively reading an image signal in a predetermined image extraction target area set in the imaging portion across the offset area from the storage portion, from the solid-state image sensor; based on the image data corresponding to each pixel of the imaging portion and a ratio between an exposure period and a transfer period per one line of the frame transfer, an accumulating unit for estimating a smear component generated in the corresponding pixel, sequentially accumulating the smear component obtained for each of the pixels arranged in the imaging portion in the column direction in accordance with the output sequence of the image signals from the solid-state image sensor, and outputting present accumulated data obtained for each column as a smear amount included in the image data corresponding the following pixel in the corresponding column; and, for each column, an initial value setting unit for setting a smear component initial value according to a smear amount generated at the offset area in the accumulating unit, as an initial value of the accumulated data, in the image extracting operation, wherein the driving circuit performs a first frame transfer operation for frame-transferring the signal charges in the image extraction target area to the storage portion, a charge removing operation for removing the signal charges from the offset area by the imaging portion charge removing means after the first frame transfer operation, and a second frame transfer operation for frame-transferring the signal charges in the offset area to the storage portion in continuous with the charge removing operation, and wherein the initial value setting unit determines the smear component initial value based on the image signal corresponding the offset area stored in the storage portion by the second frame transfer operation.

According to the present invention, after the signal charges of the image extraction target area are frame-transferred to the storage portion, the signal charges are removed from the offset area by the charge removing operation. After the signal charges are removed by the imaging portion charge removing means, the potential wells formed in the offset area accumulate the smear charges generated at the pixel passing through the imaging portion when they are moved to the storage portion by the second frame transfer operation. That is, the image signal of each line corresponding to the offset area shows the smear component amount and the smear component initial value can be determined based on the image signal of a portion or all of the lines. Here, since the first frame transferring operation, the charge removing operation and the second frame transferring operation can be performed in each frame period, together with the read operation of the image signal based on the signal charge stored in the storage portion, the obtaining operation of the image signal (extracted image) corresponding to the image extraction target area and the obtaining operation of the smear component initial value are performed with each frame period. That is, the frame period in which the extracted image is not obtained is not generated in order to obtain the smear component initial value, thereby ensuring the frame rate of the extracted image.

In the image pickup apparatus according to the present invention, the driving circuit reads, from the solid-state image sensor, a back-end offset image signal obtained based on the signal charges transferred by the second frame transfer operation from a back-end offset line adjacent to the image extraction target area of the offset area to the storage portion, and the initial value setting unit sets the smear component initial value based on the back-end offset image signal.

In the image pickup apparatus according to the present invention, when the signal charges in plurality of preceding offset lines preceding the back-end offset line of the offset area are transferred from the imaging portion to the storage portion by the second frame transfer operation, the driving circuit continuously or intermittently stops the column direction transfer to add at least some of the signal charges of the preceding offset lines to each other at an input terminal of the storage portion.

According to the present invention, the back-end offset image signal is used in determining the smear component initial value, and the information of the preceding offset lines are not required. Upon the transfer to the storage portion, the synthesizing operation of the signal charges of the preceding offset lines is performed and thus the line number corresponding to the offset area is reduced. Thereby, the size of the storage portion required for the storage of the image extraction target area and the offset area can be reduced.

In the image pickup apparatus according to the present invention, the imaging portion charge removing means performs an electronic shutter operation for removing the signal charges in the overall area of the imaging portion.

According to the present invention, a method of driving a solid-state image sensor including an imaging portion in which plurality of pixels capable of accumulating signal charges and transferring them in a column direction are arranged in a matrix, a storage portion for receiving the signal charge stored in the plurality of the pixels from the imaging portion in the column direction and temporally storing them therein, and an imaging portion charge removing means which can remove the signal charges from an area including at least an offset area adjacent to the storage portion in the imaging portion comprises a first frame transferring step for frame-transferring the signal charges in the image extraction target area to the storage portion; a charge removing step for removing the signal charges from the offset area occupied between a predetermined image extraction target area set in the imaging portion and the storage portion by the imaging portion charge removing means, after the first frame transferring step; a second frame transferring step for frame-transferring the signal charges in the offset area to the storage portion in continuous with the charge removing step; an imaging extracting step for sequentially transferring the signal charges in a column direction to the storage portion and reading an extraction target image signal corresponding to the image extraction target area from the storage portion, after the second frame transferring step; and a smear component signal obtaining step for reading a smear component signal according to a smear component included in the first line of the image extraction target area, which is an image signal obtained based on the signal charges transferred at the second frame transferring step from a back-end offset line adjacent to the image target area of the offset areas to the storage portion.

In the method according to the present invention, the second frame transferring step comprises a synthesizing step for continuously or intermittently stopping the column direction transfer to add at least some of the signal charges of the preceding offset lines to each other at a line located on input terminal of the storage portion, when the signal charges of plurality of preceding offset lines preceding the back-end offset line of the offset area are transferred from the imaging portion to the storage portion, and a back-end offset line storing step for storing the signal charges of the back-end offset line in the storage portion independent of the signal charges of the preceding offset line.

In the method according to the present invention, the second frame transferring step comprises a blank line forming step for performing the column direction transfer of the storage portion before the synthesizing step and forming at least one blank line in which the signal charges are not stored on the side of the input terminal of the storage portion.

According to the present invention, when the signal charges of the preceding offset line are synthesized at the input terminal of the storage portion, the exceeded signal charges are stored in the blank line although the synthesized signal charges exceeds the storage capacity of the potential well of the corresponding input terminal, thereby preventing the signal charges from flowing into the image extraction target area or flowing into the back-end offset line.

In the method according to the present invention, the solid-state image sensor comprises a storage portion charge removing means which can selectively remove the corresponding signal charges in a line unit when reading the signal charges stored in the storage portion, the method comprises a step for removing the signal charges transferred from the offset area to the storage portion in the first frame transferring step, by the storage portion charge removing means, and a step for removing the signal charges of the preceding offset line transferred to the storage portion in the second frame transferring step, by the storage portion charge removing means.

In the method according to the present invention, the imaging portion charge removing means can perform an electronic shutter operation for removing the signal charges of the overall area of the imaging portion, and the charge removing step performs the electronic shutter operation.

In the method according to the present invention, the imaging portion charge removing means can selectively remove the signal charges of the offset area of the imaging portion, and the method comprises a step for removing the signal charges from the offset area by the imaging portion charge removing means, before the first frame transferring step.

According to the present invention, when only the images of the image extraction target area set in a portion of the imaging portion of the solid-state image sensor are used, the smear can be easily evaluated and removed by the signal process, while ensuring high frame rate or low power consumption.

### BRIEF DESCRIPTION OF THE DRAWINGS

FIG. 1 is a schematic plan view of a general frame transfer CCD image sensor;

FIG. 2 is a schematic partial cross sectional view showing a structure of a vertical CCD shift register constituting an imaging portion and a storage portion of the general frame transfer CCD image sensor;

FIG. 3 is a schematic diagram showing a potential profile of a substrate direction in a CCD shift register of a vertical direction npn structure;

FIG. 4 is a schematic diagram illustrating a generation of smear;

FIG. 5 is a block diagram of a conventional smear removing circuit;

FIG. 6 is a schematic plan view of a frame transfer CCD image sensor according to an embodiment of the present invention;

FIG. 7 is a schematic partial cross sectional view showing a structure of a vertical CCD shift register constituting an imaging portion and a storage portion of the frame transfer CCD image sensor according to the embodiment of the present invention;

FIG. 8 is a block diagram showing a schematic structure of an image pickup apparatus according to the embodiment of the present invention;

FIG. 9 is a flowchart illustrating a method of driving the image sensor in an image extracting mode;

FIG. 10 is a schematic timing diagram illustrating a method of driving the image sensor in the image extracting mode;

FIG. 11 is a block diagram of a smear removing circuit according to the first embodiment of the present invention.

FIG. 12a is a schematic timing diagram illustrating the first example of a method of driving an image pickup apparatus according to the second embodiment of the present invention;

FIG. 12b is a schematic timing diagram illustrating the second example of the method of driving the image pickup apparatus according to the second embodiment of the present invention;

FIG. 13 is a block diagram of a smear removing circuit according to the second embodiment of the present invention;

FIG. 14 is a schematic plan view of a frame transfer CCD image sensor used in the third embodiment of the present invention;

FIG. 15 is a block diagram showing a schematic structure of an image pickup apparatus according to the third embodiment of the present invention;

FIG. 16 is a flowchart illustrating a method of driving the image sensor according to the third embodiment in the image extracting mode;

FIG. 17 is a schematic timing diagram illustrating the method of driving the image sensor according to the third embodiment in the image extracting mode;

FIG. 18 is a schematic plan view showing a movement of signal charges in the image sensor according to the third embodiment in the image extracting mode; and

FIG. 19 is a schematic diagram illustrating a potential well in the second frame transfer operation near the boundary of the imaging portion and the storage portion and a movement of the signal charges stored in the potential wells.

### DESCRIPTION OF THE PREFERRED EMBODIMENT

Hereinafter, embodiments of the present invention will be described in detail with reference to the accompanying drawings.

### First Embodiment

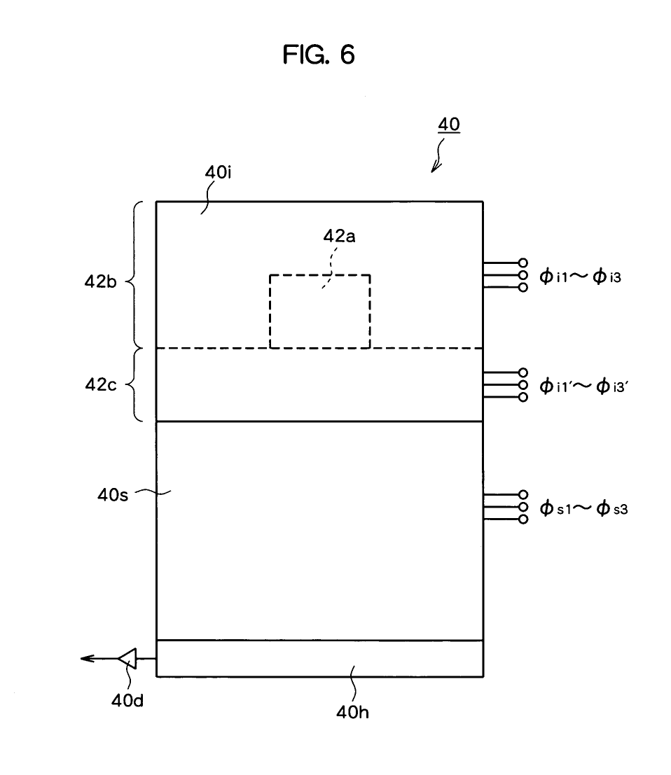

FIG. 6 is a schematic plan view of a frame transfer CCD image sensor according to an embodiment of the present invention. An image sensor 40 has an imaging portion 40i, a storage portion 40s, a horizontal transfer portion 40h and an output portion 40d formed in a surface of a semiconductor substrate. The image sensor 40 is used in shooting a still picture having high resolution by using the overall cells of the imaging portion 40i. On the other hand, in the case in which the high resolution is not required, the image sensor 40 may be used in magnifying and displaying a center portion of an image photographed by the imaging portion 40i. Also, the photographing of only the image of the center portion of the imaging portion 40i can be adequately used in a display of a preview screen or dynamic image shooting.

In the imaging portion 40i, plurality of cells for generating signal charges according to the incident light amount are arranged in a matrix. In the present embodiment, the case that a center area 42a of nine areas which are obtained by dividing the imaging portion 40i with three parts in horizontal and vertical directions becomes an image extraction target area extracted for magnification display will be described. That is, if the imaging portion 40i includes 3m lines, a preceding read area 42c (offset area) occupies the first to m-th lines from the side of the storage portion 40s, the remaining (m+1)-th to 3m-th lines correspond to the area 42b, and the center area 42 is set to the (m+1)-th to 2m-th lines of the areas 42b.

Each column of cells arranged in the imaging portion 40i in a matrix constitutes a vertical CCD shift register. The vertical CCD shift register of the imaging portion 40i comprises plurality of gate electrodes which extend on the substrate in the line direction, and, by 3-phase-driving these gate electrodes, the signal charges of each cell are vertically transferred in the vertical CCD shift register. The image sensor 40 supplies two sets of 3-phase clocks to the imaging portion 40i. The gate electrodes of the area 42b which is two-thirds of the upper side including the center area 42a on the imaging portion 40i are connected to terminals to which the set φi1 to φi3 of the first clocks are input by wiring lines in the device. On the other hand, the gate electrodes of the area (the preceding read area 42c) which is a third of the lower side of the imaging portion 40i interposed between the center area 42a and the storage portion 40s are connected to terminals to which the set φi1′ to φi3′ of the second clocks are input by the wiring lines. In other words, the vertical CCD shift register of the imaging portion 40i supplies a common 3-phase clock to two sets of clock terminals and thus frame transfer from the imaging portion 40i to the storage portion 40s can be performed, similarly to the conventional art. On the other hand, separate 3-phase clocks are applied to the area 42b and the preceding read area 42c and thus the storage and column direction transfer of the signal charge in two areas 42b and 42c can be performed separately.

The storage portion 40s has plurality of vertical CCD shift registers arranged in the line direction. Each of the vertical CCD shift registers of the storage portion 40s is provided in correspondence with each of the vertical CCD shift registers of the imaging portion 40i. In the corresponding vertical CCD shift registers of the imaging portion 40i and the storage portion 40s, the channels thereof are continuous to each other, and, by synchronously driving both shift registers, the signal charge accumulated in the imaging portion 40i can be transferred to the storage portion 40s. Also, the vertical CCD shift register of the storage portion 40s has the number of the bits according to the number of the lines of the imaging portion 40i. The vertical CCD shift register of the storage portion 40s has plurality of gate electrodes extending in the line direction, similarly to the imaging portion 40i, and the storage of the signal charges and the column direction transfer in the storage portion 40s are controlled by 3-phase clocks φs1 to φs3 applied to the gate electrodes.

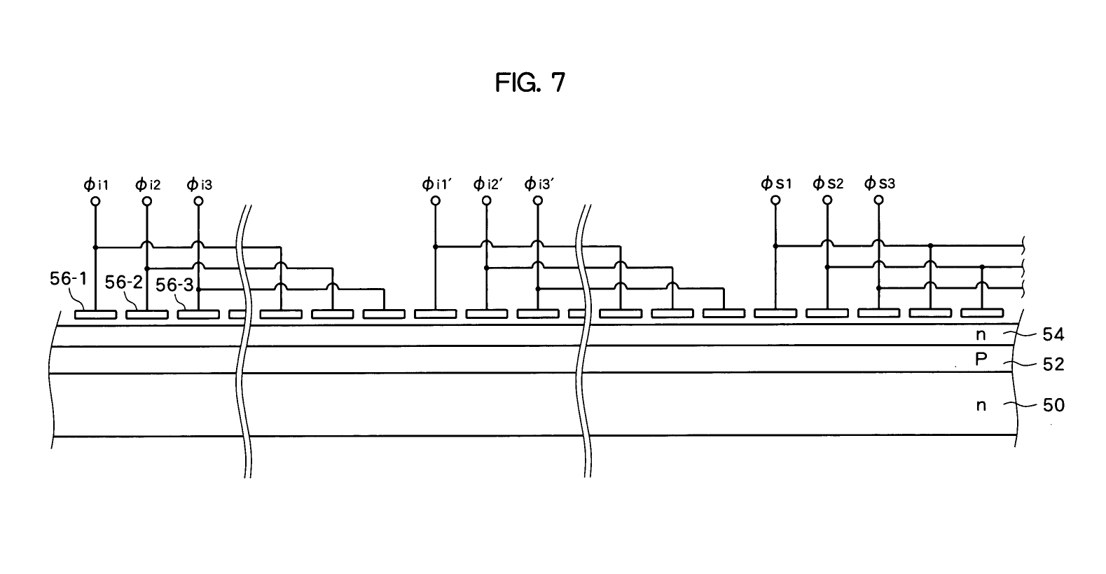

FIG. 7 is a schematic partial cross sectional view showing a structure of the vertical CCD shift register constituting an imaging portion 40i and a storage portion 40s of the frame transfer CCD image sensor. In the substrate, the npn-type structure in the depth direction thereof, which is composed of an n-type semiconductor substrate 50, a p-well 52 formed by diffusing p-type impurities thereon and an n-type area 54 formed by diffusing n-type impurities so that the depth from the surface of the substrate is shallower than that of the p-well 52, is formed. Plurality of gate electrodes 56 are arranged in the column direction on the surface of the substrate with a silicon oxide layer (not shown) between. Three-phase clock is applied to the gate electrode 56, and the channel potential in the semiconductor substrate under the silicon oxide layer is controlled according to a clock voltage. In the imaging portion, three-phase clocks φi1-φi3 are respectively applied to the gate electrodes 56-1 to 56-3 of the area 42b including the center area 42a, as described above. On the other hand, three-phase clocks φi1′ to φi3′ are respectively applied to the gate electrodes 56-1 to 56-3 of the preceding read area 42c. In the areas 42b and 42c, the vertical CCD shift registers can be separately driven. Three-phase clocks φs1-φs3 are respectively applied to the gate electrodes 56-1 to 56-3 of the storage portion 40s. Also, in the storage portion 40s, a light shielding layer is provided on the gate electrode 56, but is not shown in FIG. 7.

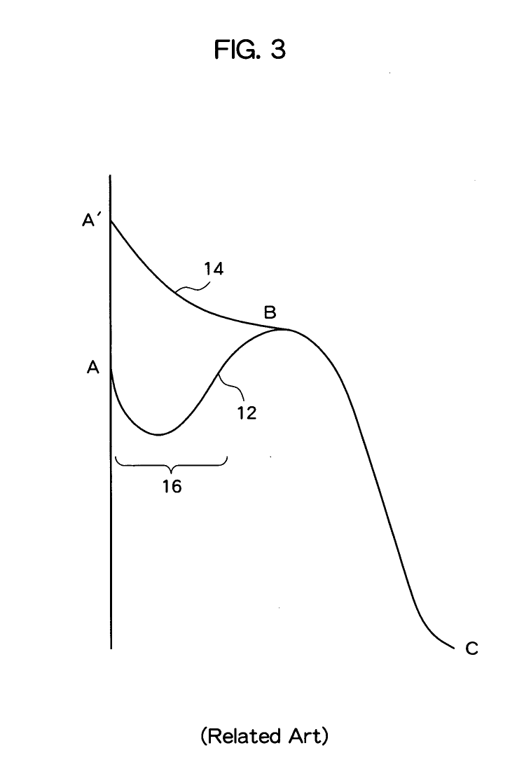

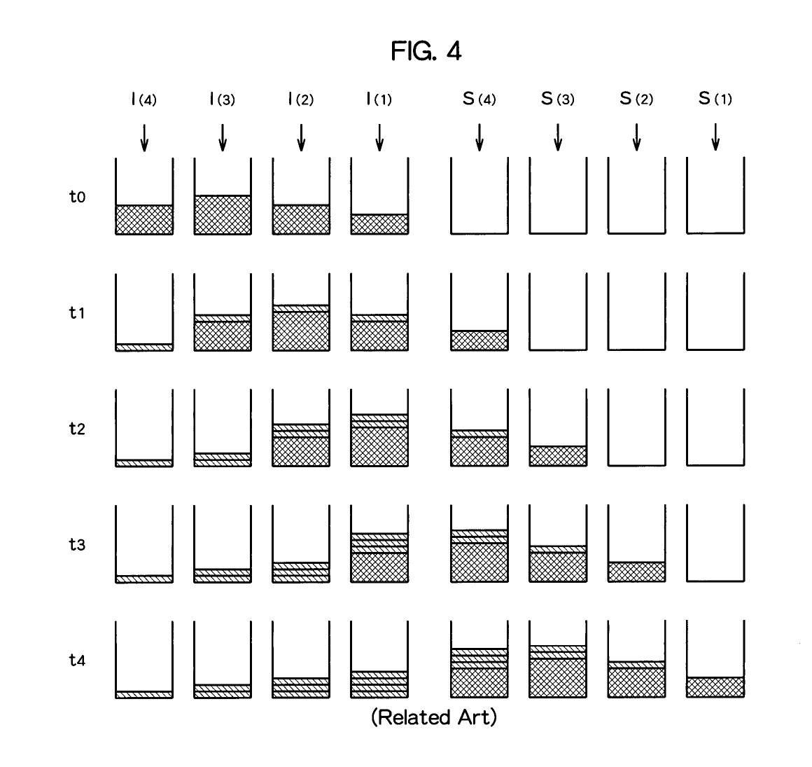

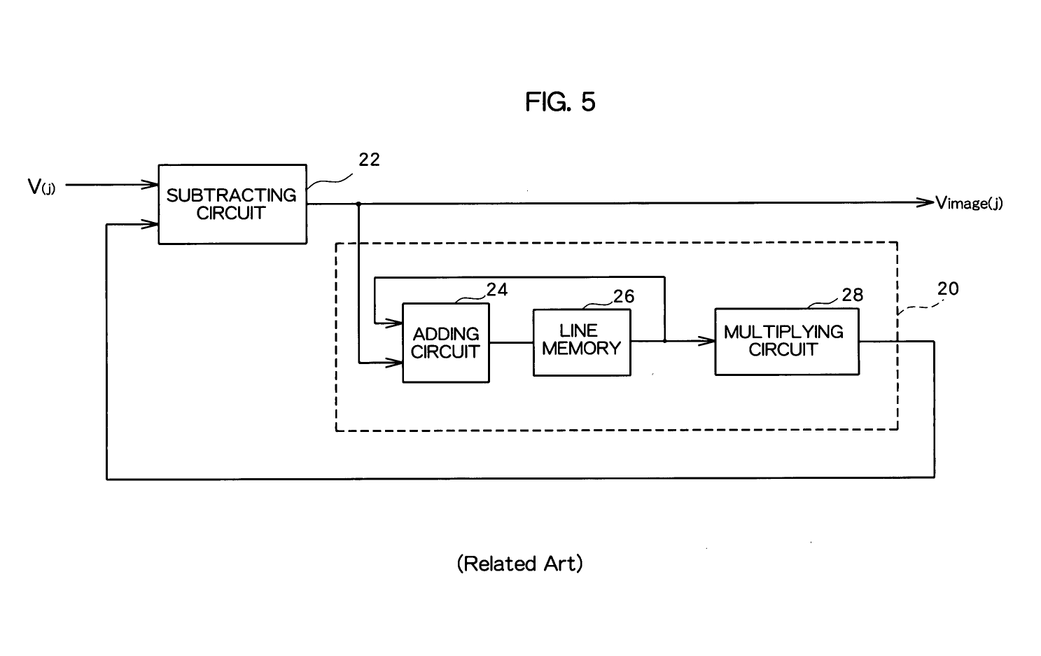

The potential profile of the substrate depth direction in the case of having the npn-type structure in the substrate direction is shown in FIG. 3. By turning on anyone or two of the gate electrodes 56-1 to 56-3 in adequate order, the potential well can be moved toward a constant direction of the channel of the vertical CCD shift register and thus the signal charges stored in the potential well can be moved. On the other hand, if all the gate electrodes 56-1 to 56-3 are turned off, the potential well disappears and the signal charges stored therein flow into the rear surface of the substrate to which the positive voltage is applied beyond the p-well 52. The technique known as the electronic shutter uses this. In this technique, the gate electrodes of the overall imaging portion 40i is turned off at the imaging start timing, the signal charges of the overall surface are removed to the rear surface of the substrate, and, thereafter, the potential well is formed under any one of the gate electrodes so that the accumulation of the signal charges generated by the exposure begins.

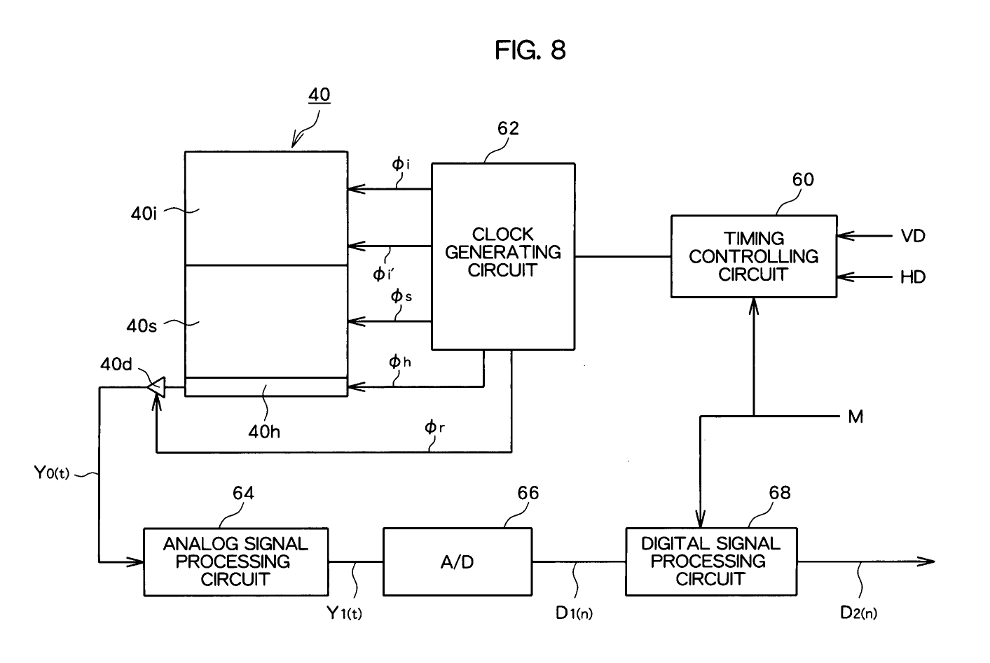

FIG. 8 is a block diagram showing a schematic structure of the image pickup apparatus using the image sensor 40. The various clocks supplied to the image sensor 40 are generated by a timing controlling circuit 60 and a clock generating circuit 62. The timing controlling circuit 60 generates various trigger signals for the clock generating circuit 62 based on a vertical synchronous signal VD and a horizontal synchronous signal HD. The clock generating circuit 62 generates the vertical transfer clock signals φi (φi1 to φi3) and φi′ (φi1′ to φi3′) for the imaging portion 40i, the vertical transfer-clock signal φs (φs1 to φs3) for the Q storage portion 40s, the horizontal transfer clock signal φh for the horizontal transfer portion 40h, and the reset pulse signal φr of the capacity of the output portion 40d, according to the trigger signals from the timing controlling circuit 60 and outputs them to each portion.

In addition, the timing controlling circuit 60 receives a shooting mode signal M showing whether it is a general mode in which the size of the shot image is the overall surface of the imaging portion 40i or an image extracting mode in which the size of the shot image is the center area 42a and then switches an operation. In the case in which the signal M designates the general mode, the timing controlling circuit 60 controls the clock generating circuit 62 such that the general operation for outputting the image signal corresponding to each line of the imaging portion 40i is performed. On the other hand, in the case that the signal M designates the image extracting mode, the timing controlling circuit 60 controls the clock generating circuit 62 such that the below-described operation is performed.

The image signal Y0(t) output from the output portion 40d is input to an analog signal processing circuit 64. The analog signal processing circuit 64 performs the processes such as sample-and-hold and AGC (Auto Gain Control) on the image signal Y0(t) and generates the image signal Y1(t) according to a predetermined format. An A/D converting circuit 66 converts the image signal Y1(t) output from the analog signal processing circuit 64 to a digital data and outputs the image data D1(n). A digital signal processing circuit 68 receives the image data D1(n) from the A/D converting circuit 66, performs the processes such as the contour correction or the integrating process in one screen unit, or the control of the color balance or the filtering in the case of the color image in addition to the below-mentioned smear removing process, and generates a new image data D2(n). The image data D2(n) is recorded in a recording medium or is converted to the analog signal by the D/A converting circuit to be used in the image display of a display device.

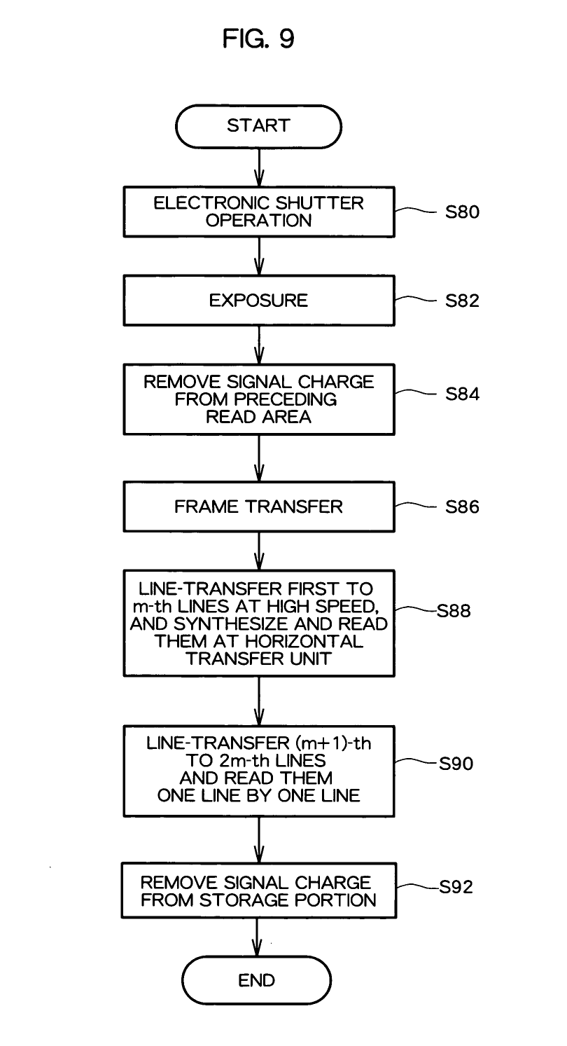

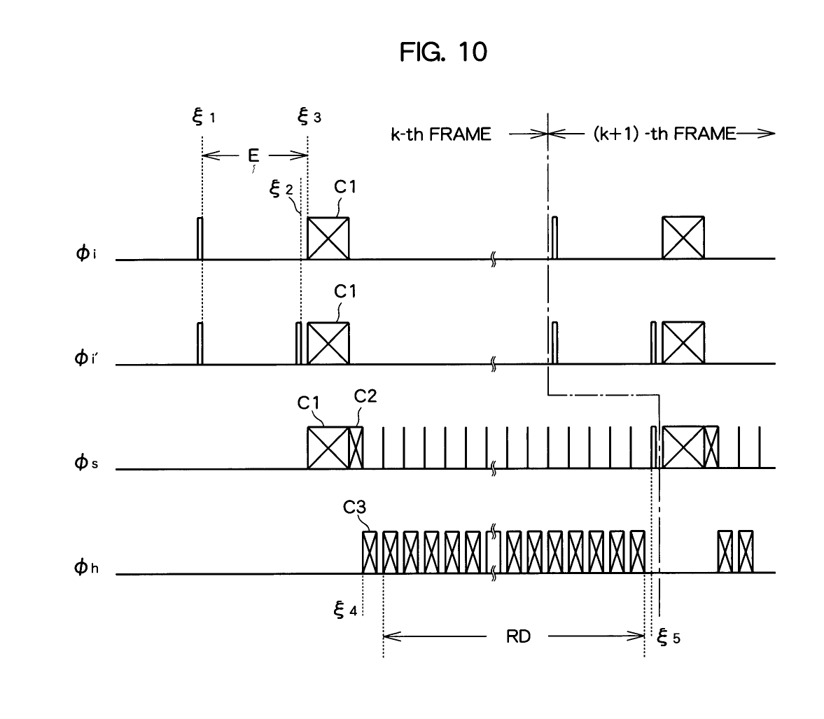

FIG. 9 is a flowchart illustrating a method of driving the image sensor in an image extracting mode. FIG. 10 is a schematic timing diagram illustrating the method of driving the image sensor. In FIG. 10, the timing of the clock operation of a transfer clock signal φi for driving the gate electrode 56 of the area 42b, a transfer clock signal φi′ for driving the gate electrode 56 of the preceding read area 42c, a transfer clock signal φs for driving the gate electrode 56 of the storage portion 40s and a transfer clock signal φh for driving the horizontal transfer portion 40h is shown. Also, in FIG. 10, the time elapses along the right direction of a horizontal axis.

First, an electronic shutter operation is performed upon the beginning of an exposure period E (S80). In the electronic shutter operation, all the transfer clocks φi1 to φi3 and φi1′ to φi3′ are turned off and, at a predetermined period preceding a timing ξ1, the potential well of each cell of the imaging portion 40i disappears. Thereby, the signal charges stored in the potential well is exhausted to the rear surface of the substrate beyond the p-well 52.

When the electronic shutter operation is completed, the clock signals (for example, for example, φi2 and φi2′) having a predetermined phase of φi and φi′ are turned on, and the potential well is formed under the corresponding gate electrode 56 of the area 42b and the preceding read area 42c (timing ξ1). From this timing, the exposure period E begins (S82). Immediately before the set exposure period E is completed, φi2′ which is turned on when the exposure period E begins is turned off (ξ2). Thereby, all the transfer clocks φi′ are turned off, the signal charges stored in each cell of the preceding read area 42c up to now are exhausted to the rear surface of the substrate (S84). At this time, φi2 is maintained at the ON state, and the signal charges stored in each cell of the area 42b including the center area 42a are maintained in each cell.

When the selective electronic shutter operation for the preceding read area 42c is completed and the exposure period E is completed, the frame transfer from the imaging portion 40i to the storage portion 40s begins (ξ3, S86). In the frame transfer, the clock generating circuit 62 generates the high-speed clocks C1 (period T) which are synchronous with each other as φi, φi′ and φs by only the cycle according to the number of the cells in the column direction of the imaging portion 40i. Thereby, the signal charges of the overall cells of the imaging portion 40i are transferred to the storage portion 40s having the light shielding layer.

The signal charges frame-transferred to the storage portion 40s are vertically transferred by the clock φs one line by one line, and, by this line transfer, the signal charges are transferred to the horizontal transfer portion 40h one line by one line. In the image extracting mode described herein, the first to m-th lines of the preceding read area 42c are transferred to the stopped horizontal transfer portion 40h with the clock C2 of the same period T as that of the frame transfer (S88). Since the horizontal transfer portion 40h is stopped at a state which the charge can be stored, the first to m-th lines of signal charges are synthesized for each line in the horizontal transfer portion 40h. Also, by the operation S84 of removing the signal charges to the rear surface of the substrate, the first to m-th lines of signal charges transferred to the horizontal transfer portion 40h are not the substantial signal but the minute noise charge, and thus it does not exceed the storing capacity of the horizontal transfer portion 40h although m lines are synthesized. When the m-th line of signal charges are line-transferred to the horizontal transfer portion 40h (ξ4), the horizontal transfer portion 40h is driven (clock C3), the synthesized signal charges are transferred to the output portion 40d, and the output portion 40d outputs the signal of one line according to the synthesized signal charge amount.

Subsequent to the line transfer and the horizontal transfer of the m-th line, the signal charges of the (m+1)-th to 2m-th lines constituting the image extraction target area are sequentially line-transferred to the horizontal transfer portion 40h at a 1H period (horizontal scan period), and are read from the output portion 40d by driving the horizontal transfer portion 40h (image read period RD, S90).

However, since the center area 42a is up to the 2m-th line, the signal charges of the (2 m+1)-th to 3m-th lines which remains in the storage portion 40s at this time does not need to be read. Accordingly, φs corresponding to the gate electrode 56 of the storage portion 40s of storing the signal charges is turned off. Thereby, all the transfer clocks φs are turned off and the remaining signal charges in the storage portion 40s are exhausted to the rear surface of the substrate (ξ5, S92).

In the operation of the image extracting mode described above, in the exposure period E, the charge exhaust of one screen imaged in the imaging portion 40i is completed in the period of from ξ3 to ξ5. Since this period is shortened compared with the period of the charge extracting operation in the general mode which all 3m lines are horizontally transferred as the horizontal transfer of the first to (m−1)-th lines and the (2 m+1)-th to 3m-th lines is omitted, the frame rate can be increased. For example, the exposure of the next frame can be performed in parallel with the line transfer in the storage portion 40s such that the frame transfer is subsequently performed at the timing ξ5.

In the above-mentioned description, the exhaust operation S92 of the remaining signal charges in the storage portion 40s is performed just after the read of the 2m-th line is completed. Here, the remaining signal charges in the storage portion 40s may be exhausted before the next frame transfer is performed. For example, the operation S84 of exhausting the signal charges from the preceding read area 42c to the rear surface of the substrate, which is performed just before the next frame is frame-transferred, and the operation S92 of exhausting the signal charges from the storage portion 40s of the preceding frame to the rear surface of the substrate can be simultaneously performed.

Next, the smear evaluation and the smear removal according to the present invention will be described. If the image signal corresponding to the cell of the j-th line of the cells of the respective lines in the imaging portion 40i is V(j) and the image signal which does not include the smear component G(j) is V_{image}(j), the j-th line of image signal V_{image}(j) in which the smear component G(j) is removed is given in the next equation by using the first to (j−1)-th lines of V_{image}(j) preceding this.

$$\begin{matrix}{V}_{image ( j )} = {V}_{( j )} - {G}_{( j )} & ( 5 ) \\ {G}_{( j )} ≡ \frac{T}{E} {\sum }_{n = 1}^{j - 1} {V}_{image ( n )} & ( 6 )\end{matrix}$$

The equations (5) and (6) have the same meaning as that of the equation (4) shown in the conventional art. In the general operation mode, in order to extract V_{image}(j) corresponding to each line of the preceding read area 42c, the smear component G(j) corresponding to any line is obtained based on the equation (6) by using the same method as that of the conventional art, and V_{image}(j) can be obtained based on the equation (5). However, the image sensor removes the signal charges stored in the preceding read area 42c to the rear surface of the substrate for the purpose of increasing the frame rate in the image extracting mode. Thereby, the information of V_{image}(j) corresponding to the first tom-th lines cannot be directly obtained. Among the right side of the equation (6), if the portions according to the ambiguous component in the image extracting mode are collected and is represented by the symbol V_{offset}, the equation (6) is as follows.

$$\begin{matrix}{G}_{( j )} = \frac{T}{E} {\sum }_{n = m + 1}^{j - 1} {V}_{image ( n )} + {V}_{offset} ( j ≧ m + 1 ) & ( 7 ) \\ {V}_{offset} ≡ \frac{T}{E} {\sum }_{n = 1}^{m} {V}_{image ( n )} & ( 8 )\end{matrix}$$

V_{offset} corresponds to the smear component mixed when each signal charge passes through the cells I(m) to I(1) upon the frame transfer. This device performs the accumulating operation represented by the equation (7) by using an estimate value of V_{offset} in the image extracting mode to obtain the smear component for the cell after I(m+1). Also, in this calculation, V_{offset} becomes an initial value of the accumulated value (an initial value of the smear component) The method of estimating V_{offset} will be described below.

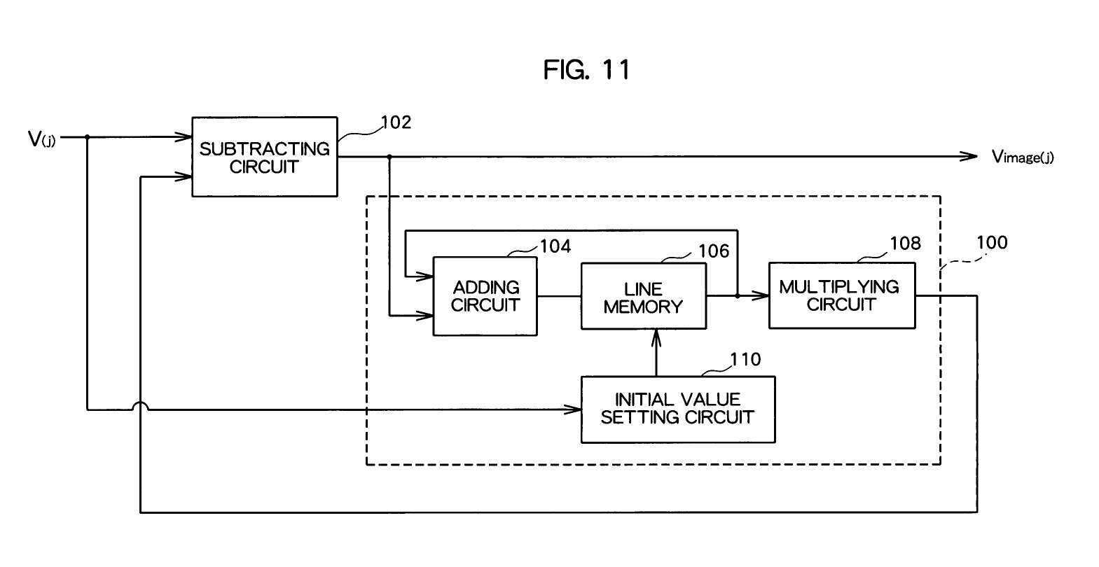

FIG. 11 is a block diagram of a smear removing circuit for removing the smear component by performing the above-mentioned signal process. This circuit receives the image signal V(j) for each line with respect to the image data D1(n) output from the A/D converting circuit 66 and generates V_{image}(j) in which the smear component is preferably removed. The smear removing circuit comprises a smear evaluation circuit 100 for obtaining the smear component G(j) included in V(j) and a subtracting circuit 102 for removing the smear component from V(j). The smear evaluation circuit 100 is the circuit for performing the operation of the right side of the equation (7) and the subtracting circuit 102 is the circuit for performing the operation of the right side of the equation (5).

The smear evaluation circuit 100 comprises an adding circuit 104, a line memory 106, a multiplying circuit 108 and an initial value setting circuit 110. The line memory 106 can store the signals of one line of the image sensor 40 and the initial value is set by the initial value setting circuit 110 in each bit. The initial value setting circuit 110 comprises an initial value estimating unit for estimating V_{offset} and an initial value setting unit for setting the value according to the estimated V_{offset} as the initial value in the line memory 106. The line memory 106 is stored with the value (E/T)·G(j) that V_{image} from the (m+1)-th to (j−1)-th lines is accumulated to the initial value for each column at the timing that the j-th line (j≧m+1) of image signal V(j) is output from the image sensor 40. The contents stored in the line memory 106 are read from the top of the line in order. The multiplying circuit 108 multiplies the value read from the line memory 106 by a coefficient (T/E) to obtain the smear component value G(j) included in the j-th line of image signal V(j) and outputs it to the subtracting circuit 102. In the subtracting circuit 102, the timing that the smear component value obtained in the multiplying circuit 108 is input to the subtracting circuit 102 is adjusted such that the smear component value corresponding to the k-th column is subtracted from the image signal value corresponding to the k-th column (k is any column number) of the image sensor 40. In this manner, the j-th line of image signal V_{image}(j) in which the smear component is preferably removed is output from the subtracting circuit 102 and is supplied to a back-end signal process (not shown). On the other hand, V_{image}(j) is also input to the adding circuit 104 of the smear evaluation circuit 100. The adding circuit 104 reads the adding value of V_{image} from the first to (j−1)-th lines from the line memory 106 and adds it to V_{image}(j) output from the subtracting circuit 102, and the added value is stored in the line memory 106. Thereby, the accumulated value of V_{image} stored in the line memory 106 is updated to the sum up to the j-th line.

But, in the image extracting mode, the initial value setting circuit 110 decides the estimate value of V_{offset} based on the (m+1)-th line of image signal V(m+1) which is the first line of the center area 42a. Here, the image of the preceding read area 42c is equal in the column direction, and the first line of the center area 42a is estimated under the assumption that it is continuous (included in) to the same image. The assumption is efficient, particularly, in the in which, for example, sky, sea and wall is seen in the preceding read area 42c. In this case, V_{image}(j)≡VO(1≦j≦m+1) is set and, from the equations (5), (6) and (8), the estimate value of V_{offset} is given by the next equation.
V_{offset}=V(m+1)·mT/E (9)

If the image signal V(m+1) is output from the image sensor 40, the initial value estimating unit in the initial value setting circuit 110 calculates the estimate value of V_{offset} for each column based on the equation (9) by using the image signal V(m+1) and sets the smear component initial value according to these estimate values in the line memory 106. In detail, in consideration of the multiplication of the coefficient (T/E) in the multiplying circuit 108, the initial value setting circuit 110 sets (E/T)·V_{offset} in the line memory 106 as the smear component initial value. In the smear evaluation circuit 100, the smear components of the line after the (m+1)-th line are accumulated to the set smear component initial value to obtain the smear component G(j) for the current image signal V(j).

The estimation of V_{offset} can be performed by a different method. In other words, if the estimate value of the image signal V_{image} (or V) in each cell of the preceding read area 42c is obtained by any method, the estimate value of V_{offset} can be determined based on this value. For example, the variation tendency in the column direction of the images from the first line to a predetermined number of the lines of the center area 42a is obtained and the image signal estimate value which is varied in the column direction of the area 42c is obtained by extrapolating the variation tendency to the preceding read area 42c.

Besides, the image signal estimate value of the preceding read area 42c can be determined according to the process result in the circuit or the application which receives the output image data output D2(n). For example, in the case in which the exposure controlling circuit controls the exposure period E based on the integral value (or the average value) of the image data of all the center area 42a, the average image data per one cell can be determined for each frame, from the integral value of the image data obtained by the exposure controlling circuit. The image signal estimate value of the preceding read area 42c can be determined based on the average image data.

Like this, the image signal estimate value of the preceding read area 42c can be determined by various methods, and, based on it, the estimate value of V_{offset} can be determined. It is preferable that the initial value setting circuit 110 can perform various kinds of estimating methods and thus a user selects and uses any one of the estimating methods such that a preferable image is obtained according to the subject.

In addition, the smear removing circuit shown in FIG. 11 is a portion of the image pickup apparatus, but may be mounted on the image signal processing device. The image signal processing device processes the image extracting mode image signal obtained by reproducing the image signal input from the exterior or recorded in a recording medium, and thus the removal of the smear component by the smear removing circuit can be performed as a portion of the process.

### Second Embodiment

The structure of the image pickup apparatus according to the second embodiment of the present invention is basically equal to that of the first embodiment. In the below description, FIGS. 6-10 are referenced and the components each having the same function are denoted by the same reference numerals and thus the description thereof is simplified. The main feature of the present image pickup apparatus is in the method of driving the image sensor 40 in the image extracting mode. The image sensor 40 of the present image pickup apparatus can separately drive the vertical CCD shift register of the preceding read area 42c and the vertical CCD shift register of the area 42b. Thereby, the operation (offset area read operation) of reading the signal charges stored in the first to m-th lines (preceding read area 42c) of the imaging portion 40i as the image signal and the operation (image extracting operation) of reading the signal charges stored in the (m+1)-th to 2m-th lines (center area 42a) as the image signal can be selectively performed.

First, the image extracting operation is the operation described by using FIG. 10 in the first embodiment. In other words, the clock generating circuit 62 removes the signal charge stored in the preceding read area 42c to the rear surface of the substrate at the end of the exposure period E and frame-transfers the signal charges of the remaining area 42b to the storage portion 40s. Thereby, the horizontal transfer operation corresponding to the first to m-th lines of the imaging portion 40i can be omitted and the image signals corresponding to the center area 42a can be obtained by the horizontal transfer number less than the general imaging mode.

On the other hand, in the offset area read operation, the clock generating circuit 62 performs the frame transfer, without removing the charge of the preceding read area 42c. Also, the signal charges of m lines corresponding to the preceding read area 42c are sequentially line-transferred to the horizontal transfer portion 40h for each line and the image signal is read from the output portion 40d by performing the horizontal transfer driving. If the read of the image signals of m lines corresponding to the preceding read area 42c is completed, the clock generating circuit 62 controls s, and moves the signal charges of the remaining (m+1)-th to 3m-th lines in the storage portion 40s to the rear surface of the substrate to thus remove it.

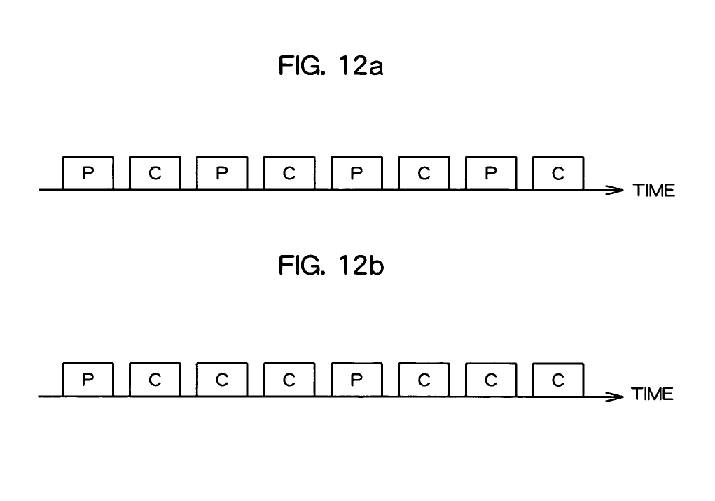

In the image extracting mode of the present image pickup apparatus, during the above-mentioned image extracting operation is repeated, the offset area read operation is inserted in a predetermined period. FIGS. 12a and 12b show the action thereof and are the schematic timing diagrams illustrating the method of driving the present image pickup apparatus. In figure, in the period labeled with a symbol “C” (1 frame period), the image extracting operation is performed and m lines of image signals corresponding to the center area 42a are output from the image sensor 40. On the other hand, in the frame period labeled with a symbol “P”, the offset area read operation is performed and m lines of image signals corresponding to the preceding read area 42c are output. In the operation shown in FIG. 12a, the offset area read operation is performed for each image extracting operation. Also, in the operation shown in FIG. 12b, one offset area read operation is inserted into three image extracting operations.

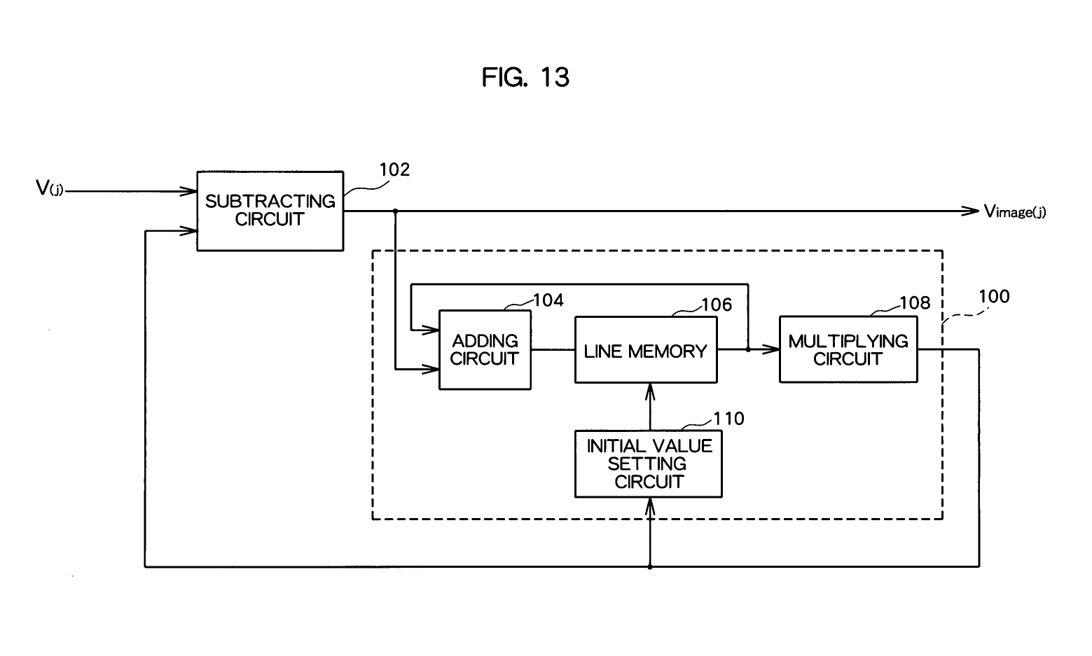

FIG. 13 is a block diagram of a smear removing circuit included in a digital signal processing circuit 68 of the present image pickup apparatus. Similar to the circuit of FIG. 11, this circuit receives the image signal V(j) for each line with respect to the image data D1(n) output from the A/D converting circuit 66 and generates the V_{image}(j) in which the smear component is preferably removed. The circuit of FIG. 13 is different from that of FIG. 11 in that the initial value setting circuit 110 can receive the accumulated value output from the smear evaluation circuit 100 as the smear component initial value. Except for the above-mentioned difference, the remaining structures of FIG. 13 are equal to those of FIG. 11.

The smear removing circuit performs the below-mentioned process using the image signal read by the offset area read operation and removes the smear component from the image signal read by the image extracting operation. The smear evaluation circuit 100 resets the stored content of each bit in the line memory 106 to 0 as the offset area read operation begins. When the image signals V(j) corresponding the first to m-th lines of the imaging portion 40i are input to the smear removing circuit by the offset area read operation, the smear evaluation circuit 100 performs the accumulating operation corresponding to the equation (6) and the accumulated result applies V_{offset} expressed by the equation (8) if the m-th line of accumulating operation is completed. Also, V_{offset} is a series of values applied for each column of the imaging portion 40i. The accumulated result is supplied to the subtracting circuit 102 and is also input to the initial value setting circuit 110.

The initial value setting circuit 110 obtains (E/T) V_{offet} as the smear component initial value based on the value of V_{offset} obtained from the output of the multiplying circuit 108 as the image extracting operation begins. Also, the coefficient (E/T) shown herein considers the multiplication of the coefficient (T/E) at the multiplying circuit 108. The initial value setting circuit 110 stores the smear component initial value obtained for each column in the corresponding bit of the line memory 106. If the image signals V(j) corresponding to the (m+1)-th to 2m-th lines of the imaging portion 40i are input to the smear removing circuit by the image extracting operation, the smear evaluation circuit 100 performs the accumulating operation expressed by the equation (7) and outputs the smear component G(j). The smear component G(j) is input to the subtracting circuit 102. The subtracting circuit 102 operates the equation (5) with respect to the each line of image signal V(j) input by the image extracting operation and outputs the image signal V_{image}(j) in which the smear component is removed.

As shown in FIG. 12b, if the image extracting operations for plurality of the frames are continuously performed, the initial value setting circuit 110 sets the smear component initial value based on V_{offset} obtained by the closest offset area read operation in the line memory 106 when each image extracting operation begins.

In the present image pickup apparatus, since the smear component initial value is obtained based on the image signal read from the preceding read area 42c by the preceding offset area read operation, the smear is preferably removed. In addition, by adjusting the frequency of the offset area read operation, the frame rate of the image from the center area 42a extracted by the image extracting operation can increase.

### Third Embodiment

In the description of the third embodiment of the present invention, the same components as those of the first and second embodiments are denoted by the same reference numerals and thus the description thereof will be simplified.

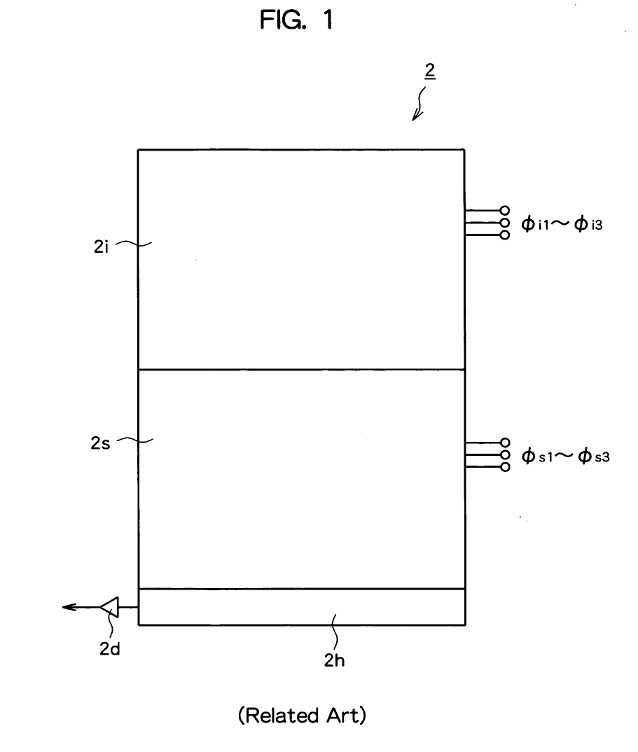

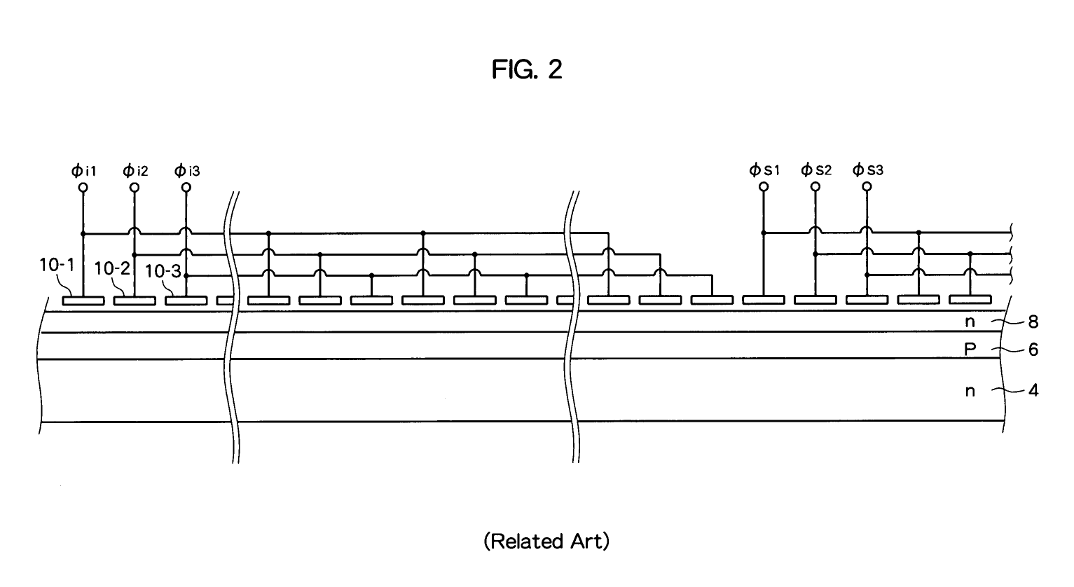

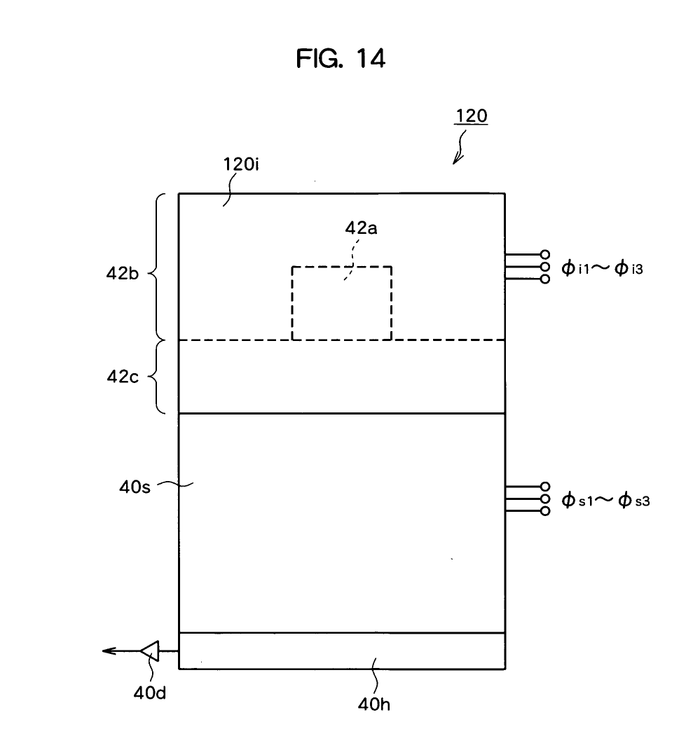

FIG. 14 is a schematic plan view of the frame transfer CCD image sensor according to the embodiment of the present invention. Although the above-mentioned image sensor 40 in which the preceding read area 42c can be driven independent of the area 42b can be used as the image sensor of the present image pickup apparatus, the image sensor 120 which performs the vertical transfer in the imaging portion with a set of 3-phase clocks φi1 to φi3 is used in the present embodiment. The basic structure of the image sensor 120 is equal to the general frame transfer CCD image sensor shown in FIG. 1 as the conventional art and the vertical CCD shift registers of the imaging portion and the storage portion have the structure shown in the schematic partial cross sectional view of FIG. 2. In other words, the imaging portion 120i is constructed such that the preceding read area 42c and the area 42b are driven by the common clocks φi1 to φi3. This is different from that of the image sensor 40. Also, the imaging portion 120i has the potential profile shown in FIG. 3 in the substrate depth direction and can perform the electronic shutter operation for collectively removing the signal charges from the overall area of the imaging portion. In addition, like the general image sensor, in the imaging portion 120i, the areas having the width of several cells along to a circumference are formed as an optical black area (OPB area). The OPB area is covered with the light shielding layer, similarly to the storage portion 40s, and the reference signal of the black level of the image is generated based on the signal charge obtained from the area. For example, here, the effective pixel area excluding the OPB area is 3m lines and the center area 42a is the central area of nine areas obtained by dividing the effective pixel area into three parts in horizontal and vertical directions.

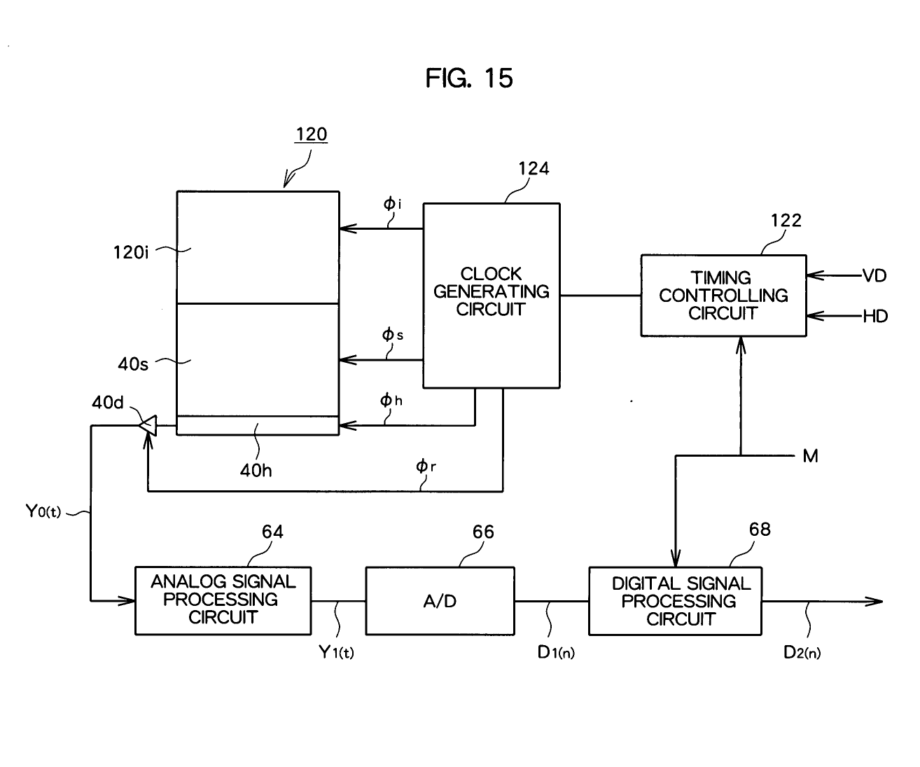

FIG. 15 is a block diagram showing the schematic structure of the image pickup apparatus using the image sensor 120. The difference between a present image pickup apparatus and those of the first and second embodiments shown in FIG. 8 is the timing controlling circuit and the clock generating circuit. The clock generating circuit 124 is different from the clock generating circuit 62 in that only φi1 to φi3 are supplied as the vertical transfer clock of the imaging portion 120i. Furthermore, the timing controlling circuit 122 and the clock generating circuit 124 drive the image sensor 120 in the image extracting mode in the sequence which is different from that of the above-mentioned embodiment. The method of driving the image sensor 120 in the present image pickup apparatus will be described below. Also, the digital signal processing circuit 68 includes the smear removing circuit therein shown in FIG. 11.

Hereinafter, the method of driving the image sensor 120 in the present image pickup apparatus will be described. The timing controlling circuit 122 receives a shooting mode signal M showing whether it is the general mode in which the size of the shot image is the overall surface of the imaging portion 120i or image extracting mode in which the size of the shot image is the center area 42a and switches the operation thereof. In the case that the signal M is the general mode, the timing controlling circuit 122 controls the clock generating circuit 124 such that the general operation for outputting the image signal corresponding to each line in the imaging portion 120i is performed. On the other hand, in the case that the signal M is the image extracting mode, the timing controlling circuit 122 and the clock generating circuit 124 drive the image sensor 120 in the below-mentioned method.

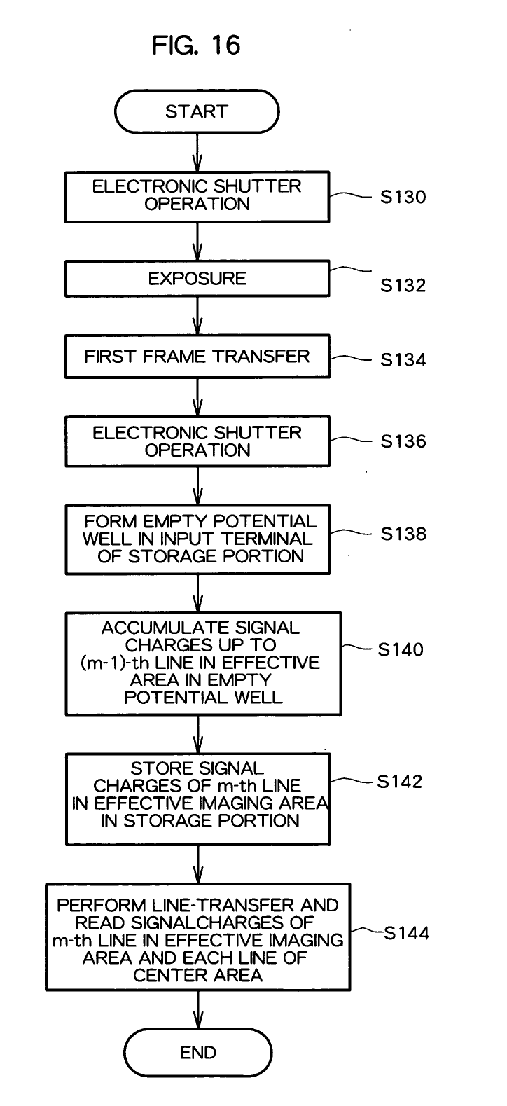

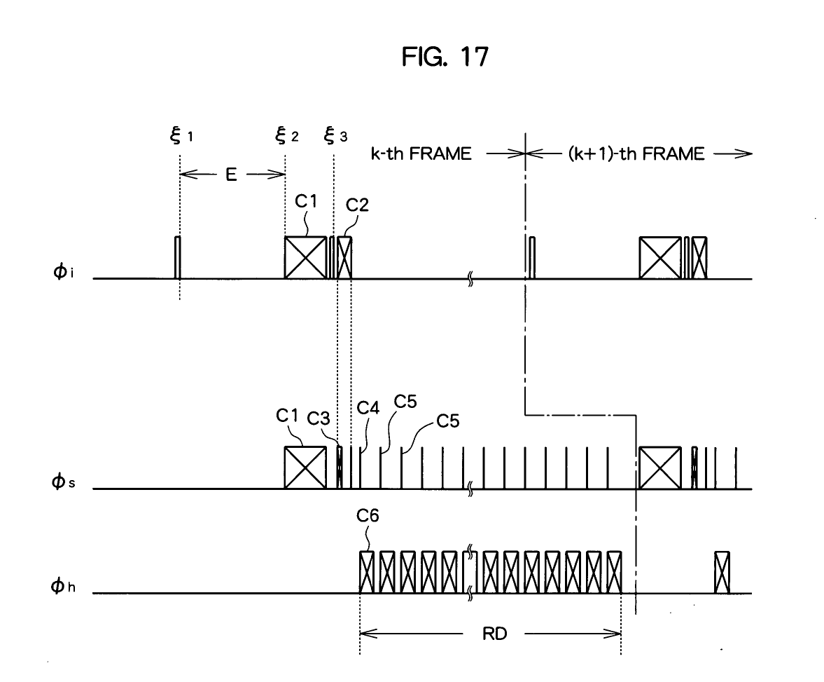

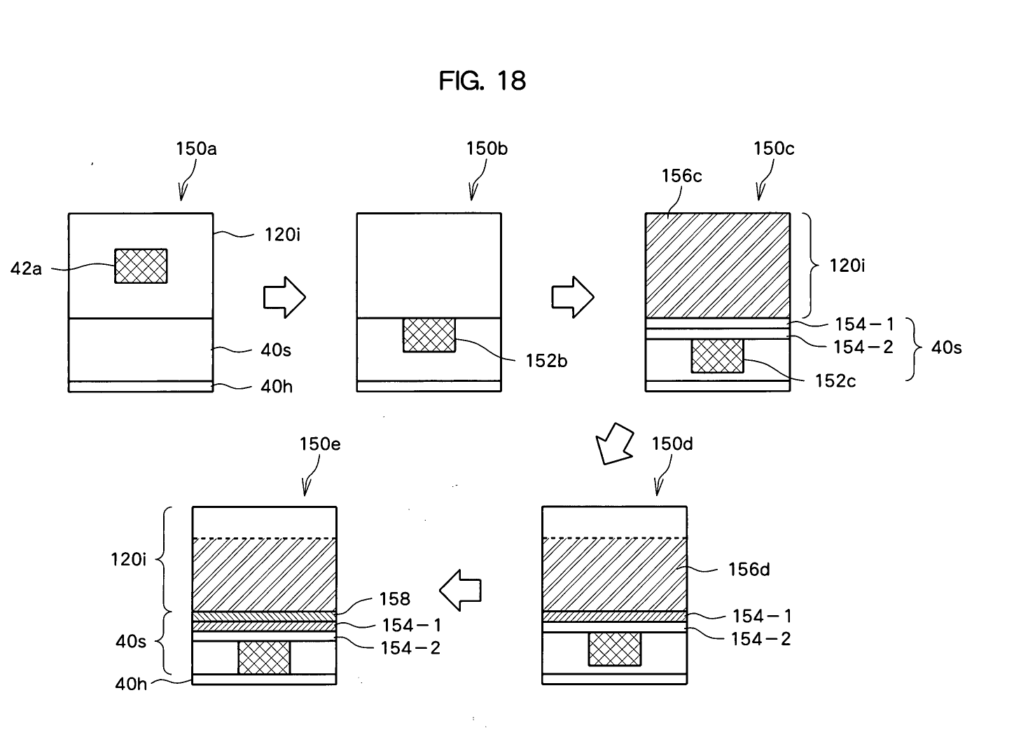

FIG. 16 is a flowchart illustrating the method of driving the image sensor in the image extracting mode and FIG. 17 is a schematic timing diagram illustrating the driving method. In FIG. 17, the timings of the clock operations of a transfer clock signal φi for driving the gate electrode 10 of the imaging portion 120i, a transfer clock signal φs for driving the gate electrode 10 of the storage portion 40s and a transfer clock signal φh for driving the horizontal transfer portion 40h are shown. Furthermore, in FIG. 17, the time elapses along the right direction of the horizontal axis. Also, FIG. 18 is a schematic plan view showing the movement of the signal charge in the image sensor 120.

First, the electronic shutter operation is performed when the exposure period E begins (S130). In the electronic shutter operation, all the transfer clocks φi1 to φi3 are turned off and, at a predetermined period preceding the timing ξ1, the potential well of each cell of the imaging portion 120i disappears. Thereby, the signal charges stored in the potential well are exhausted to the rear surface of the substrate beyond the p-well 6.

When the electronic shutter operation is completed, the clock signal having a predetermined phase of φi (for example, φi2) is turned on and the potential well is formed under the corresponding gate electrode 10 of the imaging portion 120i (timing ξ1). At this timing, the exposure period E begins (S132). Since the exposure period E is completed by the beginning of the first frame transfer operation performed in the vertical blanking period, the timing of the electronic shutter operation S132 is set to the timing which precedes the beginning of the first frame transfer operation by the predetermined exposure period E.

If the set exposure period E is completed, the first frame transfer from the imaging portion 120i to the storage portion 40s begins (ξ2, S134). In the first frame transfer, the clock generating circuit 124 generates the high-speed clock C1 (period T) at which being synchronous with each other, as φi and φs. In FIG. 18, the state 150a shows the state of the image sensor 120 when the exposure is completed and the state 150b shows the state of the image sensor 120 when the first frame transfer is completed. The number of the cycles of the generated clock C1 is determined such that the signal charges accumulated in the center area 42a are entered into the storage portion 40s when the exposure is completed. By the first frame transfer, the signal charges corresponding to the image shot at the center area 42a is moved to the area 152b.

If the overall images of the center area 42a are stored in the storage portion 40s, the electronic shutter operation is performed again and thus the signal charges are removed from the imaging portion 120i (timing ξ3, S136). Subsequently, the vertical transfer of the signal charge of the imaging portion 120i is initiated. This vertical transfer is high-speed transfer performed with the transfer clock having the same frequency as that of the above-mentioned first frame transfer. Therefore, this vertical transfer is referred to as a second frame transfer. For the second frame transfer, the clock generating circuit 124 generates the clock C2 (period T) as the clock φi for the imaging portion 120i. On the other hand, the clock generating circuit 124 generates the clocks C3 and C4 as the clock φs for the storage portion 40s.

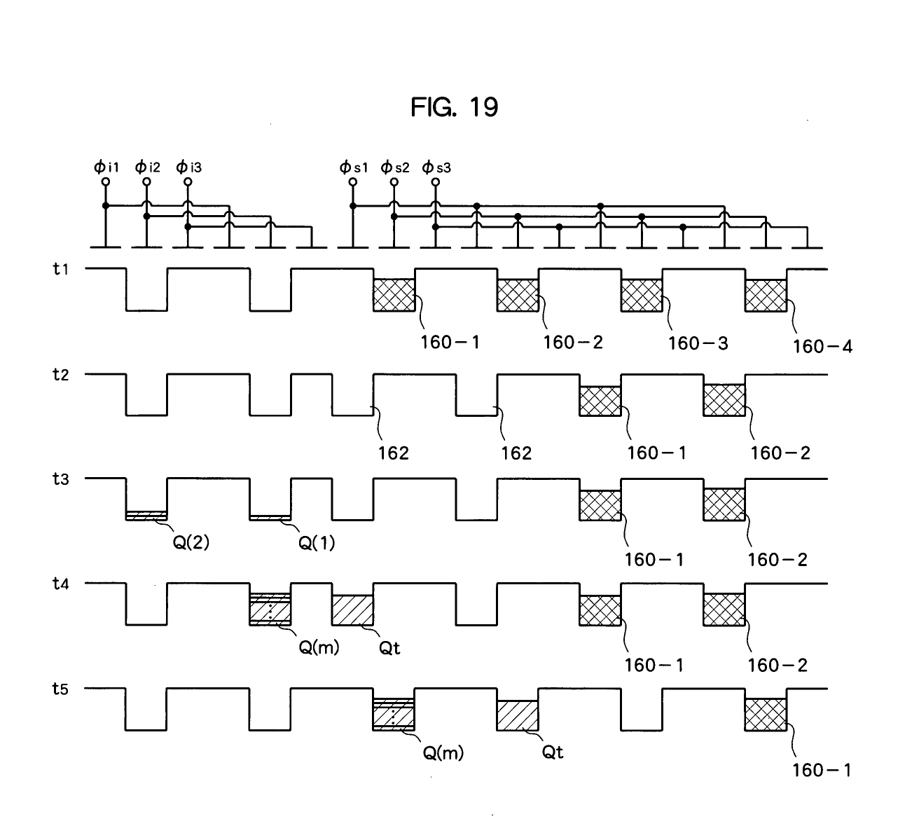

FIG. 19 is a schematic diagram illustrating the potential wells in the second frame transfer operation near the boundary of the imaging portion 120i and the storage portion 40s and the movement of the signal charges stored therein. In FIG. 19, the time t1 corresponds to the timing ξ3 at which the electronic shutter operation S136 is completed. At this timing, the clock φi2 is turned on and the potential well is formed under the gate electrode 10-2 of each cell in the imaging portion 120i. Also, in the potential wells under the gate electrodes 10-2 of a series of cells close to the imaging portion 120i in the storage portion 40s, the signal charges 160 of the center area 42a stored by the first frame transfer S134 are maintained.

The state of the time t2 shows a state that the signal charges of each cell in the storage portion 40s are vertically transferred by the clock C3. The clock C3 (period T) begins together with the clock C2. The width of the OPB area adjacent to the storage portion 40s is set to W_{OPB} and the cycle number ne of the clock C3 is set to W_{OPB} or less. The signal charge from each cell in the OPB area adjacent to the storage portion 40s does not include the smear component and the signal charge amount thereof can be basically considered to 0. Accordingly, by the vertical transfer, the empty potential well 162 according to the cycle number ne of the clock C3 is formed near the imaging portion 120i of the storage portion 40s (S138). FIG. 19 shows the case of ne=2. The clock C3 is stopped in the state that the potential wells are formed under the gate electrode 10-1 of the storage portion 40s such that the signal charges transferred from the imaging portion 120i can be received. Furthermore, in FIG. 18, the state. 150c corresponds to the state at the time t2 and two lines 154-1 and 154-2 between the imaging portion 120i and the area 152c in which the signal charges of the center area 42 are stored are composed of the empty cells.

The time t3 shows the state that the signal charges of the imaging portion 120i are vertically transferred by W_{OPB} lines and the signal charge Q(1) from the first line of the cell in the effective imaging area reaches at the cell of the output end of the vertical shift register of the imaging portion 120i. With the (W_{OPB}+1)-th cycle of the clock C2, the signal charge Q(1) is transferred to the bit (top bit) of the input terminal of the storage portion 40s and, thereafter, with the (W_{OPB}+j)-th cycle of the clock C2, the signal charge Q(j) from the j-th line of cell of the effective imaging area is transferred to the storage portion 40s. As mentioned above, since the second frame transfer operation quickly begins after the electronic shutter operation S136, the signal charge Q(j) can be basically considered to the smear component generated in the second frame transfer.

The clock generating circuit 124 continuously generates the clock C2 in the state that φs is stopped. Thereby, sequentially, the signal charge Q(j) transferred to the storage portion 40s is added to and synthesized at the potential well of the input terminal of the vertical shift register of the storage portion 40s (S140).

The time t4 shows the state of the timing that the (W_{OPB}+m−1)-th cycle of the clock C2 is completed. The signal charge Q(m) from the m-th line of cell in the effective imaging area corresponding to the last line of the preceding read area 42c reaches at the cell of the output end of the vertical shift register of the imaging portion 120i. In addition, in the top of the storage portion 40s, the signal charges Qt at which the signal charges Q(1) to Q(m−1) are accumulated are stored. In FIG. 18, the state 150d corresponds to the state of the time t4 and the signal charges Qt stored in the line 154-1 are shown by oblique lines. Also, the area 156d of net point shown in the imaging portion 120i at the state 150d shows the state that the area 156c corresponding to the imaging portion 120i upon the beginning of the second frame transfer is shifted to the side of the storage portion 40s by the frame transfer.

FIGS. 18 and 19 show the case that the accumulated signal charges Qt are stored in one potential well. On the other hand, in the case that the signal charges Qt exceed the storage capacity of the potential well of the top bit, the exceeded signal charges flow out along the channel of the vertical shift register of the storage portion 40s and flows into the potential well the adjacent bit. For example, since the number of the lines in the preceding read area 42c increases as the number of the pixels in the image sensor increases, such overflow can be generated. With respect to the overflow, like the present embodiment, the cycle number ne of the clock C3 is at least two or more to continuously form a plurality of empty potential wells. Thereby, the signal charges which overflows from the top bit are dispersed and stored to the adjacent empty potential well to prevent from being mixed to the signal charge 160 of the center area 42a.

The clock generating circuit 124 generates the clock C4 in synchronous with the clock C2 when vertically transferring the signal charge Q(m) to the storage portion 40s. Here, the clock C4 is basically φs of one cycle. By the clocks C2 and C4, the vertical shift registers of the imaging portion 120i and the storage portion 40s are synchronously driven and the signal charge Q(m) is stored in the storage portion 40s independent of the signal charge Qt (S142) The clock generating circuit 124 can complete, for example, the generation of the clock C3 at the period T and complete the second frame transfer operation, together with the completion of the generation of the clock C4. In addition, until the initial line of the area for storing the signal charges corresponding to the center area 42a reaches at the immediately previous line of the horizontal transfer portion 40h, the clock C3 may be continuously maintained.

The state of the time t5 in FIG. 19 and the state 150e of FIG. 18 show the state when finishing the second frame transfer. In FIG. 18, the signal charge Q(m) is stored in the line 158 adjacent to the imaging portion 120i. In the present embodiment, as shown in the state 150e of FIG. 18, it is constructed such that the timing that the signal charge Q(m) is stored in the storage portion 40s is equal to the timing that the signal charge of the initial line in the center area 42a is transferred to the immediately previous line of the horizontal transfer portion 40h, and the clock C3 is simultaneously stopped when completing the generation of the clock C4.

If the second frame transfer is completed, the operation for reading the voltage signal according to the signal charge obtained from the center area 42a in the storage portion 40s and the signal charge Q(m) stored in the line (the back-end offset line) 158 adjacent to the center area 42a of the preceding read areas 42c from the output portion 40d is performed (image read period RD, S144).

In the read operation S144, the clock generating circuit 124 generates the φs clock pulse C5 of one cycle for each 1H period (horizontal scan period). By the pulse C5, the signal charges frame-transferred to the storage portion 40s are vertically transferred (line-transfer) one line by one line, and, by this line transfer, the signal charges are basically transferred to the horizontal transfer portion 40h one line by one line. The clock generating circuit 124 generates the clock C6 corresponding to the horizontal scanning of 1H in continuous with the line transfer clock C5 and drives the horizontal transfer portion 40h.

Here, in the image extracting mode, in order to ensure the frame rate, the horizontal transfer operation for the signal charge of the lines which need not be read will be simplified or omitted.

For example, when a continuous plural number of times of vertical transfer operations that plurality of lines of unnecessary signal charges are transferred to the horizontal transfer portion 40h are performed in the state that the horizontal transfer portion 40h is stopped, and, if the plurality lines of the signal charges is synthesized in the horizontal transfer portion, the plurality of lines of unnecessary signal charges can be removed by one horizontal transfer operation.

Furthermore, by forming the drain structure which can remove the charges at the output end of the vertical shift register of the storage portion 40s, the unnecessary lines of signal charges are prevented from being transferred to the horizontal transfer portion 40h, thereby omitting the horizontal transfer operation. For example, as such drain structure, the structure that the gate electrode (charge removing gate electrode) TG (not shown) which can be driven independent of the gate electrode 10 of the storage portion 40s is located at the boundary between the output end of the storage portion 40s and the horizontal transfer portion 40h is conventionally known. In the gate electrode TG, the clock φtg (not shown) applied to the gate electrode TG becomes OFF voltage at the timing that the charges to be removed are stored in the potential well. Thereby, the potential well under the gate electrode TG disappears and the signal charges to be removed which are stored in the potential well is exhausted to the rear surface of the substrate on the basis of the same principle as that of the electronic shutter. On the other hand, when vertically transferring the signal charges to the horizontal transfer portion 40h, φtg is turned on/off such that the gate electrode TG is operated as a part of the 3-phase gate electrodes 10.

For example, in the first frame transfer operation S134, the signal charges of the preceding read area 42c stored in the storage portion 40s preceding the signal charges of the center area 42a can be removed by using the gate electrode TG during the second frame transfer operation. That is, the horizontal transfer operation for removing the signal charge of the preceding read area 42c can be omitted.

In addition, by accumulating the signal charges Q(1) to Q(m−1) at the time of being transferred to the storage portion 40s, the number of the lines which may include the unnecessary signal charges becomes decrease. Thereby, the image read period RD becomes shortened and thus the improvement of the frame rate can be accomplished.

Furthermore, since the signal charges of the line 154 can be removed in the area under the gate electrode TG in the read operation S144 of the image sensor including the charge removal gate electrode TG, the horizontal transfer portion 40h for the corresponding line does not need be driven. Accordingly, the clock generating circuit 124 does not generate the clock C6 with respect to the line 154, thereby suppressing the driving power or the heating of the horizontal transfer portion 40h.

Next, the smear operation of the present image pickup apparatus and the smear removal based thereon will be described. The image signal V(j) in the case that the signal charge Q(j) transferred from the preceding read area 42c to the storage portion 40s by the second frame transfer is read from the output portion 40d is expressed by the next equation.

$${V}_{( j )} = \frac{{T}^{′}}{E} {V}_{image ( j )} + \frac{T}{E} {\sum }_{n = 1}^{j - 1} {V}_{image ( n )} \qquad ( 10 )$$

Here, T′ is the time from the completion of the electronic shutter operation S136 to the initial vertical transfer operation of the second frame transfer operation. The other symbols are equal to those of the first embodiment. The image signal V(m) obtained based on the signal charge Q(m) corresponding to the back-end offset line read in the read operation S144 is as follows.

$${V}_{( m )} = \frac{{T}^{′}}{E} {V}_{image ( m )} + \frac{T}{E} {\sum }_{n = 1}^{m - 1} {V}_{image ( n )} \qquad ( 11 )$$

Comparing the equation (11) with the equation (8), T′ is as the same level as the vertical transfer period T of the frame transfer, whereas, theoretically, V(m) obtained from Q(m) is approximately equal to V_{offset}. In particular, when T′=T is set, V(m) is theoretically equal to V_{offset}. Accordingly, the initial value setting circuit 110 of the smear evaluation circuit 100 in the present image pickup apparatus receives V(m) and removes the smear component from the image signals of the center area 42a by using it as the smear component initial value V_{offset}.

In the present image pickup apparatus, the image of the center area 42a and the information for the smear component initial value are obtained at each frame of the shooting operation in the image extracting mode. The obtained information for the smear component initial value is used, for example, in the process for removing the smear component from the image signal obtained at the next frame. The smear component initial value obtained at each frame preferably reflects the variation of the subject so that the smear component can be precisely removed. Also, because a frame independent of the obtaining of the image is not required in order to obtain the smear component initial value, the obtained image frame rate can be highly maintained.

Furthermore, in the above-mentioned structure, the electronic shutter operation is performed in order to reset of the signal charge stored in the preceding read area 42c after the first frame transfer. Here, like the image sensor 40 described in the first or second embodiment, in the image pickup apparatus using the image sensor in which the preceding read area 42c can be driven independent of the area of the other imaging portion 40i, the reset operation of the preceding read area 42c after the first frame transfer becomes the operation for selectively removing only the signal charges stored in the preceding read area 42c, instead of the electronic shutter operation for the overall area of the imaging portion 40i.

Also, in addition to the above-mentioned structure for determining the smear component initial value based on V(m), the structure for determining the smear component initial value by using the other V(j) (1≦j≦m−1) is also included in the present invention. For example, according to the subject, there is a case that the smear charge amount is small. In this case, by synthesizing a plurality of lines of Q(j), the smear component can be easily detected. For example, by the above-mentioned structure, the image signal according to Qt is read and thus the initial value setting circuit 110 for estimating the smear component initial value based on the image signal according to Qt can be constructed.

In addition, in the case that the image sensor 120 does not have the OPB area, in the second frame transfer, the vertical transfer of the storage portion 40s according to the clock C3 is performed before starting the vertical transfer of the imaging portion 120i according to the clock C2 begins. By vertically transferring the signal charges of the storage portion 40s by ne bit with the clock C3 in the state that the vertical transfer of the imaging portion 120i is stopped, the blank line of the ne lines can be formed at the side of the input terminal of the storage portion 40s, similarly to the above-mentioned structure.

1. A smear evaluation circuit for obtaining a smear amount mixed into a signal charge by a frame transfer from an imaging portion to a storage portion, based on image signals obtained by a solid-state image sensor including the imaging portion in which plurality of pixels capable of accumulating signal charges and transferring them in a column direction are arranged in a matrix and the storage portion for receiving the signal charge stored in the plurality of pixels from the imaging portion in the column direction and temporally storing them therein, comprising:
based on image data corresponding to each of the pixels of a predetermined image extraction target area set in the imaging portion and a ratio between an exposure period and the transfer period per one line of the frame transfer, an accumulating unit for estimating a smear component generated at the corresponding pixel, sequentially accumulating the smear component obtained for each of the pixels arranged in the image extraction target area in the column direction in accordance with the output sequence of the image signals, and outputting present accumulated data obtained for each column as a smear amount included in image data corresponding the following pixel in the corresponding column; and
for each column, an initial value setting unit for setting a smear component initial value according to a smear amount generated at an offset area located between the storage portion and the image extraction target area of the imaging portion in the accumulating unit, as an initial value of the accumulated data.

2. The smear evaluation circuit according to claim 1, further comprising:
an initial value estimating unit for estimating image data at the offset area based on image data of a line adjacent to the offset area of the image extraction target area and determining the smear component initial value based on the estimated image data.

3. An image pickup apparatus, comprising:
a solid-state image sensor having an imaging portion in which plurality of pixels capable of accumulating a signal charges and transferring them in a column direction are arranged in a matrix, a storage portion for receiving the signal charges stored in the plurality of pixels from the imaging portion in the column direction and temporally storing them therein, and a charge removing means which can remove the signal charge generated in an offset area located between the storage portion and a predetermined image extraction target area set in the imaging portion;
a driving circuit which can perform an image extracting operation for removing the signal charge in the offset area from the solid-state image sensor by the charge removing means and selectively reading an image signal in the image extraction target area from the solid-state image sensor, and an offset area read operation for reading an image signal of the offset area from the solid-state image sensor;
based on the image data corresponding to each pixel of the imaging portion and a ratio between an exposure period and a transfer period per one line of the frame transfer, an accumulating unit for estimating a smear component generated in the corresponding pixel, sequentially accumulating the smear component obtained for each of the pixels arranged in the imaging portion in the column direction in accordance with the output sequence of the image signals from the solid-state image sensor, and outputting present accumulated data obtained for each column as a smear amount included in the image data corresponding the following pixel in the corresponding column; and
for each column, an initial value setting unit for setting a smear component initial value according to a smear amount generated at the offset area in the accumulating unit, as an initial value of the accumulated data, in the image extracting operation,
wherein the driving circuit repeatedly performs the image extracting operation and performs the offset area read operation in a predetermined period, and
the initial value setting unit sets the accumulated result of the accumulating unit in the offset area read operation as the smear component initial value used in a subsequent image extracting operation.

4. An image pickup apparatus, comprising:
a solid-state image sensor having an imaging portion in which plurality of pixels capable of accumulating a signal charge and transferring it in a column direction is arranged in a matrix, a storage portion for receiving the signal charge stored in the plurality of the pixels from the imaging portion in the column direction and temporally storing them therein and an imaging portion charge removing means which can remove the signal charge from an area including at least a predetermined offset area adjacent to the storage portion in the imaging portion;
a driving circuit which can perform an image extracting operation for selectively reading an image signal in a predetermined image extraction target area set in the imaging portion across the offset area from the storage portion, from the solid-state image sensor;
based on image data corresponding to each pixel of the imaging portion and a ratio between an exposure period and a transfer period per one line of the frame transfer, an accumulating unit for estimating a smear component generated in the corresponding pixel, sequentially accumulating the smear component obtained for each of the pixels arranged in the imaging portion in the column direction in accordance with the output sequence of the image signals from the solid-state image sensor, and outputting present accumulated data obtained for each column as a smear amount included in the image data corresponding the following pixel in the corresponding column; and
for each column, an initial value setting unit for setting a smear component initial value according to a smear amount generated at the offset area in the accumulating unit, as an initial value of the accumulated data, in the image extracting operation,
wherein the driving circuit performs a first frame transfer operation for frame-transferring the signal charge in the image extraction target area to the storage portion, a charge removing operation for removing the signal charges from the offset area by the imaging portion charge removing means after the first frame transfer operation, and a second frame transfer operation for frame-transferring the signal charges in the offset area to the storage portion in continuous with the charge removing operation, and
wherein the initial value setting unit determines the smear component initial value based on the image signal corresponding the offset area stored in the storage portion by the second frame transfer operation.

5. The image pickup apparatus according to claim 4,
wherein the driving circuit reads, from the solid-state image sensor, a back-end offset image signal obtained based on the signal charges transferred by the second frame transfer operation from a back-end offset line adjacent to the image extraction target area of the offset area to the storage portion, and
the initial value setting unit sets the smear component initial value based on the back-end offset image signal.

6. The image pickup apparatus according to claim 5,
wherein, when the signal charges in plurality of preceding offset lines preceding the back-end offset line of the offset area are transferred from the imaging portion to the storage portion by the second frame transfer operation, the driving circuit continuously or intermittently stops the column direction transfer to add at least some of the signal charges of the preceding offset lines to each other at a line located at an input terminal of the storage portion.

7. The image pickup apparatus according to claim 4,
wherein the imaging portion charge removing means performs an electronic shutter operation for removing the signal charges in the overall area of the imaging portion.

8. A method of driving a solid-state image sensor including an imaging portion in which plurality of pixels capable of accumulating signal charges and transferring them in a column direction are arranged in a matrix, a storage portion for receiving the signal charge stored in the plurality of the pixels from the imaging portion in the column direction and temporally storing them therein, and an imaging portion charge removing means which can remove the signal charges from an area including at least an offset area adjacent to the storage portion in the imaging portion, comprising the steps of:
a first frame transferring step for frame-transferring the signal charges in the image extraction target area to the storage portion;
a charge removing step for removing the signal charges from the offset area occupied between a predetermined image extraction target area set in the imaging portion and the storage portion by the imaging portion charge removing means, after the first frame transferring step;
a second frame transferring step for frame-transferring the signal charges in the offset area to the storage portion in continuous with the charge removing step;
an imaging extracting step for sequentially transferring the signal charges in a column direction to the storage portion and reading the extraction target image signal corresponding to the image extraction target area from the storage portion, after the second frame transferring step; and
a smear component signal obtaining step for reading a smear component signal according to a smear component included in the first line of the image extraction target area, which is an image signal obtained based on the signal charges transferred at the second frame transferring step from a back-end offset line adjacent to the image extraction target area of the offset areas to the storage portion.

9. The method according to claim 8,
wherein the second frame transferring step comprises a synthesizing step for continuously or intermittently stopping the column direction transfer to add at least some of the signal charges of the preceding offset lines to each other at a line located on an input terminal of the storage portion, when the signal charges of plurality of preceding offset lines preceding the back-end offset line of the offset area are transferred from the imaging portion to the storage portion, and a back-end offset line storing step for storing the signal charges of the back-end offset line in the storage portion independent of the signal charges of the preceding offset line.

10. The method according to claim 9,
wherein the second frame transferring step comprises a blank line forming step for performing the column direction transfer of the storage portion before the synthesizing step and forming at least one blank line in which the signal charges are not stored on the side of the input terminal of the storage portion.

11. The method according to claim 8,
wherein the solid-state image sensor comprises a storage portion charge removing means which can selectively remove the corresponding signal charges in a line unit when reading the signal charges stored in the storage portion,
wherein the method comprises a step for removing the signal charges transferred from the offset area to the storage portion in the first frame transferring step, by the storage portion charge removing means, and a step for removing the signal charges of the preceding offset line transferred to the storage portion in the second frame transferring step, by the storage portion charge removing means.

12. The method according to claim 8,
wherein the imaging portion charge removing means can perform an electronic shutter operation for removing the signal charges of the overall area of the imaging portion, and the charge removing step performs the electronic shutter operation.

13. The method according to claim 8,
wherein the imaging portion charge removing means can selectively remove the signal charges of the offset area of the imaging portion, and
wherein the method comprises a step for removing the signal charges from the offset area by the imaging portion charge removing means, before the first frame transferring step.
